(19) United States
(12) Patent Application Publication
(10) Pub. No.: US 2026/0013216 A1
(43) Pub. Date: Jan. 8, 2026

(54) SEMICONDUCTOR DEVICE

(71) Applicant: Samsung Electronics Co., Ltd., Suwon-si (KR)

(72) Inventors: Byung Ho Moon, Suwon-si (KR); Dong Hoon Hwang, Suwon-si (KR); Kyung Ho Kim, Suwon-si (KR); Min Woo Kim, Suwon-si (KR); Jae Ho Jeon, Suwon-si (KR)

(21) Appl. No.: 19/176,815

(22) Filed: Apr. 11, 2025

(30) Foreign Application Priority Data
Jul. 2, 2024 (KR) 10-2024-0086583

(51) Int. Cl. H10D 84/83; H10D 84/01

(52) U.S. Cl. CPC H10D 84/8316; H10D 84/8312; H10D 84/83138; H10D 84/832; H10D 84/0147; H10D 84/0151

(57) ABSTRACT

A semiconductor device includes a substrate, an active pattern extending in a first direction on the substrate, a plurality of lower nanosheets stacked on the active pattern and spaced apart from each other in a vertical direction, a nanosheet isolation layer including an insulating material on an upper surface of an uppermost nanosheet of the plurality of lower nanosheets, a plurality of upper nanosheets stacked on an upper surface of the nanosheet isolation layer and spaced apart from each other in the vertical direction, a gate electrode extending in a second direction different from the first direction on the active pattern, the gate electrode extending on the plurality of lower nanosheets, the nanosheet isolation layer, and the plurality of upper nanosheets, and an inner spacer on opposing sidewalls of the gate electrode between either adjacent ones of the upper nanosheets, or adjacent ones of the lower nanosheets.

### CROSS-REFERENCE TO RELATED APPLICATION

This application claims priority from Korean Patent Application No. 10-2024-0086583 filed on Jul. 2, 2024, in the Korean Intellectual Property Office, and all the benefits accruing therefrom under 35 U.S.C. 119, the contents of which in its entirety are herein incorporated by reference.

### TECHNICAL FIELD

Various example embodiments relate to a semiconductor device. Specifically, the present disclosure relates to a semiconductor device including a MBCFET™ (Multi-Bridge Channel Field Effect Transistor).

### BACKGROUND

As one of the scaling techniques to increase the density of integrated circuit devices, multi-gate transistors have been proposed, in which a fin-shaped or nanowire-shaped silicon body is formed on a substrate, and gates are formed on the surface of the silicon body.

Since these multi-gate transistors utilize a three-dimensional channel, they may be easier to scale. Additionally, current control capability may be improved without increasing the gate length of the multi-gate transistor. Furthermore, SCE (short channel effect), in which the potential of the channel region is influenced by the drain voltage, may be effectively suppressed.

### SUMMARY

The present disclosure may provide a semiconductor device with improved reliability by forming an internal spacer only in the NMOS transistor in a structure where PMOS transistors and NMOS transistors are stacked in a vertical direction (or vice versa).

The aspects of the present disclosure are not limited to those mentioned above, and other aspects may be clearly understood by those skilled in the art from the description below.

According to some embodiments of the present disclosure, a semiconductor device includes a substrate; an active pattern extending in a first direction on the substrate; a plurality of lower nanosheets stacked on the active pattern and spaced apart from each other in a vertical direction perpendicular to a surface of the substrate; a nanosheet isolation layer on an upper surface of an uppermost nanosheet of the plurality of lower nanosheets, the nanosheet isolation layer including an insulating material; a plurality of upper nanosheets stacked on an upper surface of the nanosheet isolation layer and spaced apart from each other in the vertical direction; a gate electrode extending in a second direction that intersects the first direction on the active pattern, the gate electrode extending on the plurality of lower nanosheets, the nanosheet isolation layer, and the plurality of upper nanosheets; and inner spacers on opposing sidewalls of the gate electrode in the first direction. The inner spacers are between adjacent ones of the upper nanosheets, and the plurality of lower nanosheets are free of the inner spacers therebetween, or the inner spacers are between adjacent ones of the lower nanosheets, and the plurality of upper nanosheets are free of the inner spacers therebetween.

According to some embodiments of the present disclosure, a semiconductor device includes a substrate; an active pattern extending in a first direction on the substrate; a plurality of nanosheets stacked on the active pattern and spaced apart from each other in a vertical direction perpendicular to a surface of the substrate; a gate electrode extending in a second direction that intersects the first direction on the active pattern, the gate electrode extending on the plurality of nanosheets; a lower source/drain region on the active pattern at one side of the gate electrode in the first direction; an upper source/drain region on the lower source/drain region at the one side of the gate electrode in the first direction, wherein the upper source/drain region is spaced apart from the lower source/drain region in the vertical direction; and an inner spacer between the gate electrode and one of the lower source/drain region or the upper source/drain region. The gate electrode and another of the lower source/drain region or the upper source/drain region are free of the inner spacer therebetween.

According to some embodiments of the present disclosure, a semiconductor device includes a substrate; an active pattern extending in a first direction on the substrate; a plurality of lower nanosheets stacked on the active pattern and spaced apart from each other in a vertical direction perpendicular to a surface of the substrate; a nanosheet isolation layer on an upper surface of an uppermost nanosheet of the plurality of lower nanosheets, the nanosheet isolation layer comprising an insulating material; a plurality of upper nanosheets stacked on an upper surface of the nanosheet isolation layer and spaced apart from each other in the vertical direction; a lower gate electrode extending in a second direction that intersects the first direction on the active pattern, the lower gate electrode extending on the plurality of lower nanosheets and a lower portion of the nanosheet isolation layer; an upper gate electrode extending in the second direction and spaced apart from the lower gate electrode in the vertical direction, the upper gate electrode extending on an upper portion of the nanosheet isolation layer and the plurality of upper nanosheets; a lower source/drain region on the active pattern and in contact with respective sidewalls of the plurality of lower nanosheets in the first direction; an upper source/drain region on the lower source/drain region and in contact with respective sidewalls of the plurality of upper nanosheets in the first direction, the upper source/drain region spaced apart from the lower source/drain region in the vertical direction; a gate insulating layer between the lower source/drain region and the lower gate electrode, and between the upper source/drain region and the upper gate electrode; and an inner spacer between the upper source/drain region and the gate insulating layer on the upper gate electrode. The inner spacer directly contacts the upper source/drain region, and the gate insulating layer directly contacts the lower source/drain region.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a schematic plan view or layout diagram for explaining a semiconductor device according to some embodiments of the present disclosure;

FIG. 2 is a cross-sectional view taken along line A-A′ of FIG. 1;

FIG. 3 is a cross-sectional view taken along line B-B′ of FIG. 1;

FIGS. 4 to 27 are intermediate stage diagrams for explaining methods of fabricating semiconductor devices according to some embodiments of the present disclosure;

FIGS. 28 and 29 are cross-sectional views for explaining semiconductor devices according to some other embodiments of the present disclosure;

FIGS. 30 and 31 are cross-sectional views for explaining semiconductor devices according to some other embodiments of the present disclosure;

FIGS. 32 to 44 are intermediate stage diagrams for explaining methods of fabricating semiconductor devices according to some other embodiments of the present disclosure; and

FIGS. 45 and 46 are cross-sectional views for explaining semiconductor devices according to another several embodiments of the present disclosure.

### DETAILED DESCRIPTION OF EMBODIMENTS

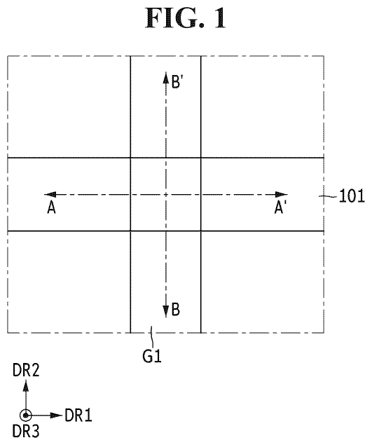

Hereinafter, various example embodiments will be described with reference to FIGS. 1 to 3. The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present. Likewise, when components are “immediately” adjacent to one another, no intervening components may be present. Spatially relative terms such as ‘on,’ ‘upper,’ ‘upper portion,’ ‘upper surface,’ ‘below,’ ‘lower,’ ‘lower portion,’ ‘lower surface,’ ‘side surface,’ and the like may be denoted by reference numerals and refer to the drawings, except where otherwise indicated typically relative to a reference layer or element, such as a substrate. It will be understood that such spatially relative terms are intended to encompass different orientations of the device in use or operation in addition to the orientation depicted in the figures.

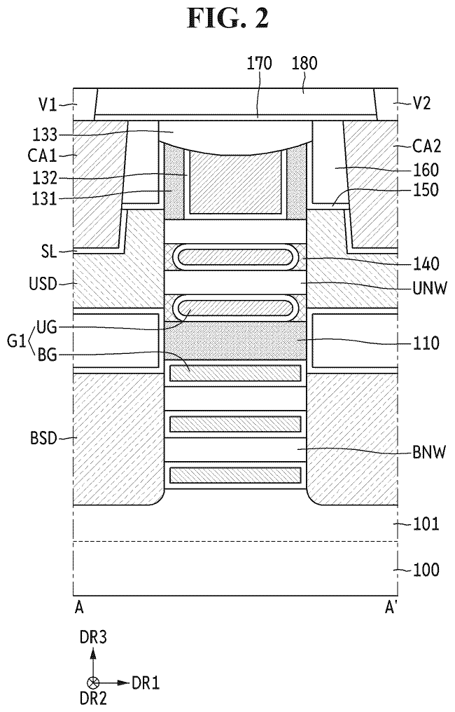

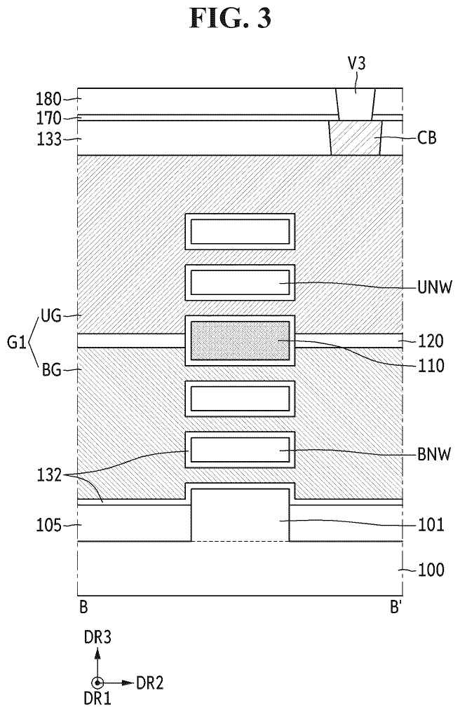

FIG. 1 is a plan view or layout diagram for explaining the semiconductor device according to some embodiments of the present disclosure. FIG. 2 is a cross-sectional view taken along line A-A′ of FIG. 1. FIG. 3 is a cross-sectional view taken along the line B-B′ of FIG. 1.

Referring to FIGS. 1 to 3, the semiconductor device according to some embodiments of the present disclosure includes a substrate 100, an active pattern 101, a field insulating layer 105, a plurality of bottom nanosheets BNW (also referred to herein as lower nanosheets), a nanosheet isolation layer 110, a plurality of upper nanosheets UNW, a gate electrode G1, a gate isolation layer 120, a bottom source/drain region BSD (also referred to herein as a lower source/drain region), and an upper source/drain region USD, a gate spacer 131, a gate insulating layer 132, a capping pattern 133, an inner spacer 140, a first etching stop layer 150, a first interlayer insulating layer 160, first and second source/drain contacts CA1, CA2, a silicide layer SL, a gate contact CB, a second etching stop layer 170, a second interlayer insulating layer 180, and first to third vias V1, V2, V3.

The substrate 100 may be a silicon substrate or SOI (silicon-on-insulator). Alternatively, the substrate 100 may include silicon germanium, SGOI (silicon germanium on insulator), indium antimonide, lead telluride compounds, indium arsenide, indium phosphide, gallium arsenide, or gallium antimonide, but the present disclosure is not limited thereto.

Hereinafter, each of the first horizontal direction DR1 and the second horizontal direction DR2 may be defined as a direction parallel to an upper surface of the substrate 100. The second horizontal direction DR2 may be defined as a direction different from the first horizontal direction DR1. The vertical direction DR3 may be defined as a direction perpendicular to each of the first horizontal direction DR1 and the second horizontal direction DR2. That is, the vertical direction DR3 may be defined as a direction perpendicular to the upper surface of the substrate 100.

The active pattern 101 may protrude from the substrate 100 in the vertical direction DR3. The active pattern 101 may extend in the first horizontal direction DR1 on the substrate 100. The active pattern 101 may be a part of the substrate 100 and may include an epitaxial layer grown from the substrate 100.

The field insulating layer 105 may be disposed on the substrate 100. The field insulating layer 105 may surround the sidewalls of the active pattern 101. The term “surround” (or “cover” or “fill”) as may be used herein may not require completely surrounding (or covering or filling) the described elements or layers, but may, for example, refer to partially surrounding (or covering or filling) the described elements or layers, for example, with voids or other spaces throughout. For example, the upper surface of the active pattern 101 may protrude in the vertical direction DR3 than the upper surface of the field insulating layer 105. However, the present disclosure is not limited thereto. In some other example embodiments, the upper surface of the active pattern 101 may be formed on the same plane as (i.e., coplanar with) the upper surface of the field insulating layer 105. The field insulating layer 105 may include, for example, an oxide layer, a nitride layer, an oxynitride layer, or a combination thereof.

A plurality of bottom nanosheets BNW may be disposed on the active pattern 101. The plurality of bottom nanosheets BNW may be spaced apart from the active pattern 101 in the vertical direction DR3. That is, the bottom surface of the bottom nanosheet of the plurality of bottom nanosheets BNW may be spaced apart from the upper surface of the active pattern 101 in the vertical direction DR3. The plurality of bottom nanosheets BNW may include a plurality of nanosheets stacked and spaced apart from each other in the vertical direction DR3 on the active pattern 101. In FIGS. 2 and 3, the plurality of bottom nanosheets BNW are illustrated as including two nanosheets stacked in the vertical direction DR3, but this is for convenience of explanation only. In some other example embodiments, the plurality of bottom nanosheets BNW may include three or more nanosheets stacked in the vertical direction DR3. For example, the plurality of bottom nanosheets BNW may include silicon (Si).

The nanosheet isolation layer 110 may be disposed on the upper surface of the uppermost nanosheets of the plurality of bottom nanosheets BNW. For example, the nanosheet isolation layer 110 may be spaced apart from the upper surface of the uppermost nanosheet of the plurality of bottom nanosheets BNW in the vertical direction DR3. The nanosheet isolation layer 110 may include an insulating material. For example, the nanosheet isolation layer 110 may include at least one of silicon nitride (SiN), silicon oxycarbonitride (SiOCN), silicon boron carbonitride (SiBCN), silicon carbonitride (SiCN), silicon oxynitride (SiON), and combinations thereof. However, the present disclosure is not limited thereto.

The plurality of upper nanosheets UNW may be disposed on the upper surface of the nanosheet isolation layer 110. The plurality of upper nanosheets UNW may be spaced apart from the upper surface of the nanosheet isolation layer 110 in the vertical direction DR3. That is, the bottom surface of the lowermost nanosheet of the plurality of upper nanosheets UNW may be spaced apart from the upper surface of the nanosheet isolation layer 110 in the vertical direction DR3. The plurality of upper nanosheets UNW may include a plurality of nanosheets stacked and spaced apart from each other in the vertical direction DR3 on the upper surface of the nanosheet isolation layer 110. In FIGS. 2 and 3, the plurality of upper nanosheets UNW are illustrated as including two nanosheets stacked in the vertical direction DR3, but this is for convenience of explanation only. In some other example embodiments, the plurality of upper nanosheets UNW may include three or more nanosheets stacked in the vertical direction DR3. For example, the plurality of upper nanosheets UNW may include silicon (Si). For example, the sidewall of each of the plurality of bottom nanosheets BNW, the nanosheet isolation layer 110, and the plurality of upper nanosheets UNW in the first horizontal direction DR1 may be aligned in the vertical direction DR3. However, the present disclosure is not limited thereto.

The gate electrode G1 may extend in the second horizontal direction DR2 on the active pattern 101 and the field insulating layer 105. The gate electrode G1 may surround each of the plurality of bottom nanosheets BNW, the nanosheet isolation layer 110, and the plurality of upper nanosheets UNW. For example, the gate electrode G1 may include a bottom gate electrode BG (also referred to herein as a lower gate electrode) and an upper gate electrode UG. The bottom gate electrode BG may extend in the second horizontal direction DR2 on the active pattern 101 and the field insulating layer 105. For example, the bottom gate electrode BG may surround the plurality of bottom nanosheets BNW and a portion of the nanosheet isolation layer 110. For example, the upper surface of the bottom gate electrode BG may be formed higher than the bottom surface of the nanosheet isolation layer 110. Also, the upper surface of the bottom gate electrode BG may be formed lower than the upper surface of the nanosheet isolation layer 110.

The upper gate electrode UG may extend in the second horizontal direction DR2 on the upper surface of the bottom gate electrode BG. The upper gate electrode UG may overlap with the bottom gate electrode BG in the vertical direction DR3. The upper gate electrode UG may be spaced apart from the bottom gate electrode BG in the vertical direction DR3. For example, the upper gate electrode UG may surround each of another portion of the nanosheet isolation layer 110 and the plurality of upper nanosheets UNW. For example, the bottom surface of the upper gate electrode UG may be formed lower than the upper surface of the nanosheet isolation layer 110. The bottom gate electrode BG and the upper gate electrode UG may include the same material, but the present disclosure is not limited to this. In some other example embodiments, the bottom gate electrode BG and the upper gate electrode UG may include different materials.

For example, each of the bottom gate electrode BG and the upper gate electrode UG may include titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel-platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof.

The gate isolation layer 120 may be disposed between the upper surface of the bottom gate electrode BG and the bottom surface of the upper gate electrode UG. The gate isolation layer 120 may electrically isolate the bottom gate electrode BG and the upper gate electrode UG in the vertical direction DR3. For example, the gate isolation layer 120 may be in contact with the upper surface of the bottom gate electrode BG and the bottom surface of the upper gate electrode UG, respectively. For example, the upper surface of the gate isolation layer 120 may be formed lower than the upper surface of the nanosheet isolation layer 110. Also, the bottom surface of the gate isolation layer 120 may be formed higher than the bottom surface of the nanosheet isolation layer 110. The gate isolation layer 120 may include an insulating material. However, the present disclosure is not limited thereto. In some other example embodiments, the gate isolation layer 120 may include a conductive material.

The gate spacer 131 may extend in the second horizontal direction DR2 along both (e.g., opposing) sidewalls of the gate electrode G1 in the first horizontal direction DR1 on the upper surface of the uppermost nanosheet of the plurality of upper nanosheets UNW and the field insulating layer 105. For example, the gate spacer 131 may include at least one of silicon nitride (SiN), silicon oxynitride (SiON), silicon carbonitride (SiCN), silicon oxycarbonitride (SiOCN), silicon boron nitride (SiBN), silicon oxyboron nitride (SiOBN), silicon oxynitride (SiOC), and combinations thereof. However, the present disclosure is not limited thereto.

The bottom source/drain region BSD may be disposed on at least one side of the bottom gate electrode BG on the active pattern 101. For example, the bottom source/drain region BSD may be disposed on both (e.g., opposing) sides of the bottom gate electrode BG on the active pattern 101. That is, the bottom source/drain region BSD may overlap with the bottom gate electrode BG in the first horizontal direction DR1. For example, the bottom source/drain region BSD may be in contact with both (e.g., opposing) sidewalls of the plurality of bottom nanosheets BNW in the first horizontal direction DR1. For example, the upper surface of the bottom source/drain region BSD may be formed higher than the upper surface of the uppermost nanosheet of the plurality of bottom nanosheets BNW. For example, the upper surface of the bottom source/drain region BSD may be formed lower than the bottom surface of the nanosheet isolation layer 110. However, the present disclosure is not limited thereto. In some other example embodiments, the upper surface of the bottom source/drain region BSD may be formed higher than the upper surface of the nanosheet isolation layer 110.

The upper source/drain region USD may be disposed on at least one side of the upper gate electrode UG on the upper surface of the bottom source/drain region BSD. For example, the upper source/drain region USD may be disposed on both (e.g., opposing) sides of the upper gate electrode UG on the upper surface of the bottom source/drain region BSD. That is, the upper source/drain region USD may overlap with the upper gate electrode UG in the first horizontal direction DR1. For example, the upper source/drain region USD may overlap with the bottom source/drain region BSD in the vertical direction DR3. The upper source/drain region USD may be spaced apart from the bottom source/drain region BSD in the vertical direction DR3. For example, the upper source/drain region USD may be in contact with both (e.g., opposing) sidewalls of the plurality of upper nanosheets UNW in the first horizontal direction DR1. For example, the upper surface of the upper source/drain region USD may be formed higher than the upper surface of the uppermost nanosheet of the plurality of upper nanosheets UNW. For example, the bottom surface of the upper source/drain region USD may be formed lower than the bottom surface of the lowermost nanosheet of the plurality of upper nanowires UNW. For example, the bottom surface of the upper source/drain region USD may be formed higher than the upper surface of the nanosheet isolation layer 110. However, the present disclosure is not limited thereto. In some other example embodiments, the bottom surface of the upper source/drain region USD may be formed lower than the upper surface of the nanosheet isolation layer 110.

The gate insulating layer 132 may be disposed between the bottom gate electrode BG and the active pattern 101. The gate insulating layer 132 may be disposed between the bottom gate electrode BG and the field insulating layer 105. The gate insulating layer 132 may be disposed between the bottom gate electrode BG and the plurality of bottom nanosheets BNW. The gate insulating layer 132 may be disposed between the bottom gate electrode BG and the bottom source/drain region BSD. The gate insulating layer 132 may be disposed between the bottom gate electrode BG and the nanosheet isolation layer 110. The gate insulating layer 132 may be disposed between the nanosheet isolation layer 110 and the gate isolation layer 120.

Additionally, the gate insulating layer 132 may be disposed between the upper gate electrode UG and the gate spacer 131. The gate insulating layer 132 may be disposed between the upper gate electrode UG and the plurality of upper nanosheets UNW. The gate insulating layer 132 may be disposed between the upper gate electrode UG and the upper source/drain region USD. The gate insulating layer 132 may be disposed between the upper gate electrode UG and the nanosheet isolation layer 110. For example, the gate insulating layer 132 may be in contact with the bottom source/drain region BSD. For example, the gate insulating layer 132 is not in contact with the upper source/drain region USD. The gate insulating layer 132 may be spaced apart from the upper source/drain region USD in the first horizontal direction DR1.

The gate insulating layer 132 may include at least one of silicon oxide, silicon oxynitride, silicon nitride, or a high-k dielectric material with a higher dielectric constant than silicon oxide. High-k dielectric materials may include, for example, one or more of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

The semiconductor device according to some example embodiments may include a NC (Negative Capacitance) FET utilizing a negative capacitor. For example, the gate insulating layer 132 may include a ferroelectric material layer with ferroelectric properties and a paraelectric material layer with paraelectric properties.

The ferroelectric material layer may have a negative capacitance, while the paraelectric material layer may have a positive capacitance. For example, when two or more capacitors are connected in series and each of their capacitances has a positive value, the total capacitance may decrease than the capacitance of each individual capacitor. On the other hand, when at least one of the capacitances of the two or more capacitors connected in series has a negative value, the total capacitance may have a positive value and be greater than the absolute value of each individual capacitance.

When the ferroelectric material layer with a negative capacitance and the paraelectric material layer with a positive capacitance are connected in series, the total capacitance value of the ferroelectric material layer and the paraelectric material layer connected in series may be increased. By utilizing the increase in total capacitance value, the transistor including the ferroelectric material layer may have a subthreshold swing (SS) of less than 60 mV/decade at room temperature.

The ferroelectric material layer may have ferroelectric properties. The ferroelectric material layer may include, for example, at least one of hafnium oxide, hafnium zirconium oxide, barium strontium titanium oxide, barium titanium oxide, and lead zirconium titanium oxide. In another example, hafnium zirconium oxide may be a material in which zirconium (Zr) is doped into hafnium oxide. In another example, hafnium zirconium oxide may be a compound of hafnium (Hf), zirconium (Zr), and oxygen (O).

The ferroelectric material layer may further include (e.g., may be doped with) a dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). Depending on which ferroelectric material the ferroelectric material layer includes, the type of dopant included in the ferroelectric material layer may vary.

When the ferroelectric material layer includes hafnium oxide, the dopant included in the ferroelectric material layer may include, for example, at least one of gadolinium (Gd), silicon (Si), zirconium (Zr), aluminum (Al), and yttrium (Y).

When the dopant is aluminum (Al), the ferroelectric material layer may include 3 to 8 at % (atomic %) of aluminum. Here, the ratio of the dopant may be a ratio of aluminum to the sum of hafnium and aluminum.

When the dopant is silicon (Si), the ferroelectric material layer may include 2 to 10 at % of silicon. When the dopant is yttrium (Y), the ferroelectric material layer may include 2 to 10 at % of yttrium. When the dopant is gadolinium (Gd), the ferroelectric material layer may include 1 to 7 at % of gadolinium. When the dopant is zirconium (Zr), the ferroelectric material layer may include 50 to 80 at % of zirconium.

The paraelectric material layer may have paraelectric properties. The paraelectric material layer may include, for example, at least one of silicon oxide and a high-k metal oxide. The metal oxide included in the paraelectric material layer may include, for example, at least one of hafnium oxide, zirconium oxide, and aluminum oxide, but is not limited thereto.

The ferroelectric material layer and the paraelectric material layer may include the same material. While the ferroelectric material layer may have ferroelectric properties, the paraelectric material layer may not have ferroelectric properties. For example, when the ferroelectric material layer and the paraelectric material layer include hafnium oxide, the crystal structure of the hafnium oxide included in the ferroelectric material layer is different from the crystal structure of the hafnium oxide included in the paraelectric material layer.

The ferroelectric material layer may have a thickness having ferroelectric properties. The thickness of the ferroelectric material layer may be, for example, 0.5 to 10 nm, but is not limited thereto. Since the critical thickness exhibiting ferroelectric properties may vary for each ferroelectric material, the thickness of the ferroelectric material layer may vary depending on the ferroelectric material.

As an example, the gate insulating layer 132 may include a single ferroelectric material layer. In another example, the gate insulating layer 132 may include a plurality of ferroelectric material layers spaced apart from each other. The gate insulating layer 132 may have a stacked layer structure in which the plurality of ferroelectric material layers and the plurality of paraelectric material layers are alternately stacked.

The inner spacer 140 may be disposed on both (e.g., opposing) sidewalls of the upper gate electrode UG in the first horizontal direction DR1 between the adjacent upper nanosheets UNW. The inner spacer 140 may be disposed on both (e.g., opposing) sidewalls of the upper gate electrodes UG in the first horizontal direction DR1 for upper gate electrodes UG between the upper surface of the nanosheet isolation layer 110 and the bottom surface of the lowermost nanosheet of the plurality of upper nanosheets UNW. The inner spacer 140 may be disposed between the upper gate electrodes UG and the upper source/drain region USD.

However, the inner spacer 140 is not disposed on both (e.g., opposing) sidewalls of the bottom gate electrode BG in the first horizontal direction DR1 between the adjacent bottom nanosheets BNW. The inner spacer 140 is not disposed on both (e.g., opposing) sidewalls of the bottom gate electrodes BG in the first horizontal direction DR1 for bottom gate electrodes BG between the upper surface of the active pattern 101 and the bottom surface of the lowermost nanosheet of the plurality of bottom nanosheets BNW. The inner spacer 140 is not disposed on both (e.g., opposing) sidewalls of the bottom gate electrodes BG in the first horizontal direction DR1 between the bottom surface of the nanosheet isolation layer 110 and the upper surface of the uppermost nanosheet of the plurality of bottom nanosheets BNW.

For example, the inner spacer 140 may be in contact with the sidewall of the upper source/drain region USD in the first horizontal direction DR1. However, the inner spacer 140 is not in contact with the bottom source/drain region BSD. That is, the lower source/drain region BSD may be free of the inner spacers 140 between the lower source/drain region BSD and the lower gates BG. For example, the inner spacer 140 may be in contact with the plurality of upper nanosheets UNW. However, the inner spacer 140 is not in contact with the plurality of bottom nanosheets BNW. That is, the lower nanosheets BNW may be free of the inner spacers 140 therebetween. For example, the inner spacer 140 may be in contact with the upper surface of the nanosheet isolation layer 110. For example, between the upper gate electrode UG and the upper source/drain region USD, the inner spacer 140 may be in contact with the gate insulating layer 132.

For example, the sidewall of the inner spacer 140 in the first horizontal direction DR1 facing the sidewall of the upper gate electrode UG may be formed to be concave toward the upper source/drain region USD. For instance, the inner spacer 140 may include at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), and combinations thereof. However, the present disclosure is not limited thereto.

The first interlayer insulating layer 160 may cover each of the bottom source/drain region BSD and the upper source/drain region USD on the field insulating layer 105. For example, the first interlayer insulating layer 160 may be disposed between the upper surface of the bottom source/drain region BSD and the bottom surface of the upper source/drain region USD. For example, the first interlayer insulating layer 160 may be disposed on both (e.g., opposing) sidewalls in the first horizontal direction DR1 of the nanosheet isolation layer 110 and the gate spacer 131, respectively. For example, the first interlayer insulating layer 160 may include at least one of silicon oxide, silicon nitride, silicon oxynitride, and a low-k material. The low-k material may include, for example, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethylCycloTetraSiloxane (OMCTS), HexaMethylDiSiloxane (HMDS), TriMethylSilyl Borate (TMSB), DiAcetoxyDitertiaryButoxySiloxane (DADBS), TriMethylSilil Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped silicon Oxide), OSG (Organo Silicate Glass), SiLK, Amorphous Fluorinated Carbon, silica aerogels, silica xerogels, mesoporous silica, or combinations thereof, but the present disclosure is not limited thereto.

The first etching stop layer 150 may be disposed between the first interlayer insulating layer 160 and the field insulating layer 105. The first etching stop layer 150 may be disposed between the first interlayer insulating layer 160 and the bottom source/drain region BSD. The first etching stop layer 150 may be disposed between the first interlayer insulating layer 160 and the upper source/drain region USD. The first etching stop layer 150 may be disposed between the first interlayer insulating layer 160 and the sidewall of the nanosheet isolation layer 110 in the first horizontal direction DR1. The first etching stop layer 150 may be disposed between the first interlayer insulating layer 160 and the sidewall of the gate spacer 131 in the first horizontal direction DR1. For example, the first etching stop layer 150 may be formed conformally. For example, the first etching stop layer 150 may be in contact with the sidewall of the inner spacer 140 in the first horizontal direction DR1 on the bottom surface of the upper source/drain region USD. For example, the first etching stop layer 150 may be in contact with the gate insulating layer 132 on the upper surface of the bottom source/drain region BSD. For example, the first etching stop layer 150 may include at least one of aluminum oxide, aluminum nitride, hafnium oxide, zirconium oxide, silicon oxide, silicon nitride, silicon oxynitride, and a low-k material.

The capping pattern 133 may extend in the second horizontal direction DR2 on the upper surfaces of the gate spacer 131, the gate insulating layer 132, and the upper gate electrode UG, respectively. For example, the bottom surface of the capping pattern 133 may be in contact with the first etching stop layer 150. However, the present disclosure is not limited thereto. In some other example embodiments, the sidewall of the capping pattern 133 may be in contact with the first etching stop layer 150. For example, the capping pattern 133 may include at least one of silicon nitride (SiN), silicon oxynitride (SiON), silicon oxide (SiO₂), silicon carbonitride (SiCN), silicon oxycarbonitride (SiOCN), and combinations thereof. However, the present disclosure is not limited thereto.

The first source/drain contact CA1 may be disposed on the first side of the upper gate electrode UG. The first source/drain contact CA1 may be disposed above the upper source/drain region USD disposed on the first side of the upper gate electrode UG. The first source/drain contact CA1 may penetrate the first interlayer insulating layer 160 and the first etching stop layer 150 in the vertical direction DR3 and extend into the inside of the upper source/drain region USD disposed on the first side of the upper gate electrode UG. The first source/drain contact CA1 may be electrically connected to the upper source/drain region USD disposed on the first side of the upper gate electrode UG.

The second source/drain contact CA2 may be disposed on the second side of the upper gate electrode UG facing the first side of the upper gate electrode UG in the first horizontal direction DR1. The second source/drain contact CA2 may be disposed above the upper source/drain region USD disposed on the second side of the upper gate electrode UG. The second source/drain contact CA2 may penetrate the first interlayer insulating layer 160 and the first etching stop layer 150 in the vertical direction DR3 and extend into the inside of the upper source/drain region USD disposed on the second side of the upper gate electrode UG. The second source/drain contact CA2 may be electrically connected to the upper source/drain region USD disposed on the second side of the upper gate electrode UG.

For example, the upper surface of each of the first and second source/drain contacts CA1, CA2 may be formed on the same plane as (i.e., coplanar with) the upper surface of the first interlayer insulating layer 160. In FIG. 2, each of the first and second source/drain contacts CA1, CA2 is illustrated as being formed as a single layer, but the present disclosure is not limited thereto. In some other example embodiments, each of the first and second source/drain contacts CA1, CA2 may be formed as multiple layers. Each of the first and second source/drain contacts CA1, CA2 may include a conductive material.

The silicide layer SL may be disposed along the interface between the upper source/drain region USD disposed on the first side of the upper gate electrode UG and the first source/drain contact CA1. Further, the silicide layer SL may be disposed along the interface between the upper source/drain region USD disposed on the second side of the upper gate electrode UG and the second source/drain contact CA2. For example, the silicide layer SL may include a metal silicide material.

The gate contact CB may penetrate the capping pattern 133 in the vertical direction DR3 to be connected to the upper gate electrode UG. For example, the upper surface of the gate contact CB may be formed on the same plane as (i.e., coplanar with) the upper surface of the capping pattern 133. However, the present disclosure is not limited thereto. In some other example embodiments, the upper surface of the gate contact CB may be formed higher than the upper surface of the capping pattern 133. In FIG. 3, the gate contact CB is illustrated as being formed as a single layer, but the present disclosure is not limited thereto. In some other example embodiments, the gate contact CB may be formed as multiple layers. The gate contact CB may include a conductive material.

The second etching stop layer 170 may be disposed on the upper surfaces of the first interlayer insulating layer 160, the capping pattern 133, the gate contact CB, and the first and second source/drain contacts CA1, CA2, respectively. For example, the second etching stop layer 170 may be formed conformally. In FIGS. 2 and 3, the second etching stop layer 170 is illustrated as being formed as a single layer, but the present disclosure is not limited thereto. In some other example embodiments, the second etching stop layer 170 may be formed as multiple layers. For example, the second etching stop layer 170 may include at least one of aluminum oxide, aluminum nitride, hafnium oxide, zirconium oxide, silicon oxide, silicon nitride, silicon oxynitride, and a low-k material. The second interlayer insulating layer 180 may be disposed on the second etching stop layer 170. The second interlayer insulating layer 180 may include at least one of, for example, silicon oxide, silicon nitride, silicon oxynitride, and a low-k material.

The first via V1 may penetrate the second interlayer insulating layer 180 and the second etching stop layer 170 in the vertical direction DR3 to be connected to the first source/drain contact CA1. The second via V2 may penetrate the second interlayer insulating layer 180 and the second etching stop layer 170 in the vertical direction DR3 to be connected to the second source/drain contact CA2. The third via V3 may penetrate the second interlayer insulating layer 180 and the second etching stop layer 170 in the vertical direction DR3 to be connected to the gate contact CB. In FIGS. 2 and 3, each of the first to third vias V1, V2, V3 is illustrated as being formed as a single layer, but the present disclosure is not limited thereto. In some other example embodiments, each of the first to third vias V1, V2, V3 may be formed as multiple layers. Each of the first to third vias V1, V2, V3 may include a conductive material.

For example, the plurality of upper nanosheets UNW, the upper gate electrode UG, and the upper source/drain region USD may form an NMOS transistor. Additionally, the plurality of bottom nanosheets BNW, the bottom gate electrode BG, and the bottom source/drain region BSD may form a PMOS transistor. In other words, the inner spacer 140 is disposed on the sidewalls in the first horizontal direction DR1 of the upper gate electrode UG forming the NMOS transistor, and is not disposed on the sidewalls in the first horizontal direction DR1of the bottom gate electrode BG forming the PMOS transistor.

The semiconductor device according to some embodiments of the present disclosure features a structure where the PMOS transistor and the NMOS transistor are stacked in the vertical direction DR3, with the inner spacer 140 being disposed on the NMOS transistor but not on the PMOS transistor. As a result, in the structure where the PMOS transistor and the NMOS transistor are stacked in the vertical direction DR3, the semiconductor device according to some embodiments of the present disclosure may improve reliability by reducing the leakage current of the NMOS transistor, where the inner spacer 140 is disposed, and preventing degradation of the PMOS transistor, where the inner spacer 140 is not disposed.

Hereinafter, a method of fabricating semiconductor device according to some embodiments of the present disclosure will be described with reference to FIGS. 2 to 27.

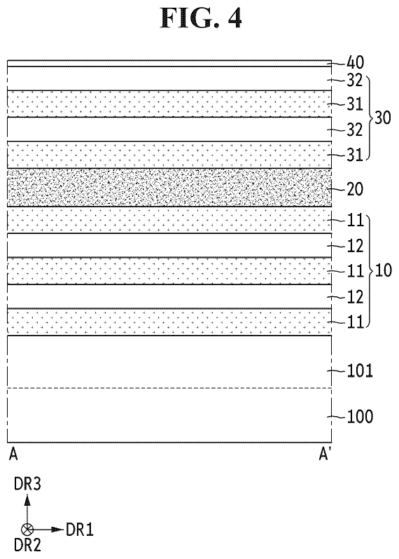

FIGS. 4 to 27 are intermediate stage diagrams for explaining the method of fabricating a semiconductor device according to some embodiments of the present disclosure.

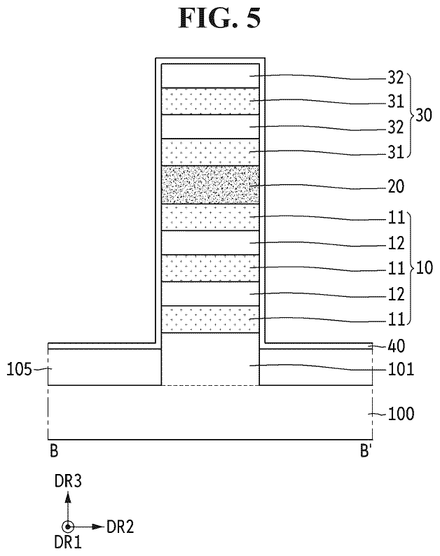

Referring to FIGS. 4 and 5, a first stacked structure 10, an isolation material layer 20, and a second stacked structure 30 may be sequentially stacked on the substrate 100. For example, the first stacked structure 10 may be formed on the substrate 100. The first stacked structure 10 may include a first sacrificial layer 11 and a first semiconductor layer 12, which are alternately stacked on the substrate 100. For example, the first sacrificial layer 11 may be formed at each of the lowermost and uppermost portions of the first stacked structure 10. However, the present disclosure is not limited thereto. In some other example embodiments, the first semiconductor layer 12 may be formed on the uppermost portion of the first stacked structure 10.

For example, the isolation material layer 20 may be formed on the upper surface of the first stacked structure 10. For example, the second stacked structure 30 may include a second sacrificial layer 31 and a second semiconductor layer 32, which are alternately stacked on the upper surface of the isolation material layer 20. For example, the second sacrificial layer 31 may be formed at the lowermost portion of the second stacked structure 30, and the second semiconductor layer 32 may be formed on the uppermost portion of the second stacked structure 30. However, the present disclosure is not limited thereto. In some other example embodiments, the second sacrificial layer 31 may also be formed on the uppermost portion of the second stacked structure 30.

For example, each of the first sacrificial layer 11 and the second sacrificial layer 31 may include silicon germanium (SiGe). Each of the first semiconductor layer 12 and the second semiconductor layer 32 may include, for example, silicon (Si). For example, the isolation material layer 20 may include silicon germanium (SiGe). For example, the concentration of germanium (Ge) contained in the isolation material layer 20 may be greater than the concentration of germanium (Ge) contained in each of the first sacrificial layer 11 and the second sacrificial layer 31.

Subsequently, a portion of each of the second stacked structure 30, the isolation material layer 20, and the first stacked structure 10 may be etched. After such an etching process has been performed, the sidewall in the second horizontal direction DR2 of each of the remaining second stacked structure 30, isolation material layer 20, and first stacked structure 10 may have a continuous slope profile. While each of the second stacked structure 30, the isolation material layer 20, and the first stacked structure 10 is etched, a portion of the substrate 100 may also be etched. As a result, an active pattern 101 extending in the first horizontal direction DR1 at the lower portion of the first stacked structure 10 may be defined.

Subsequently, the field insulating layer 105 may be formed to surround the sidewalls of the active pattern 101 on the substrate 100. Subsequently, a pad oxide layer 40 may be formed to cover the field insulating layer 105, the exposed active pattern 101, the first stacked structure 10, the isolation material layer 20, and the second stacked structure 30. For example, the pad oxide layer 40 may be formed conformally. For example, the pad oxide layer 40 may include silicon oxide (SiO₂).

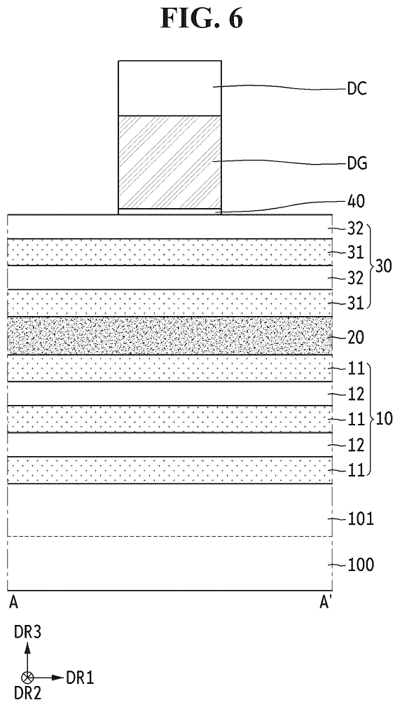

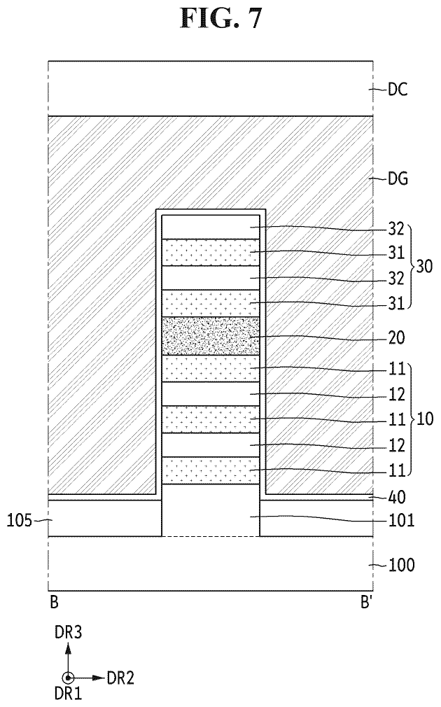

Referring to FIGS. 6 and 7, a dummy gate DG and a dummy capping pattern DC extending in the second horizontal direction DR2 may be formed on the field insulating layer 105 and the second stacked structure 30. The dummy capping pattern DC may be formed on the upper surface of the dummy gate DG. For example, portions of the pad oxide layer 40 except the portion overlapping the dummy gate DG in the vertical direction DR3 may be removed.

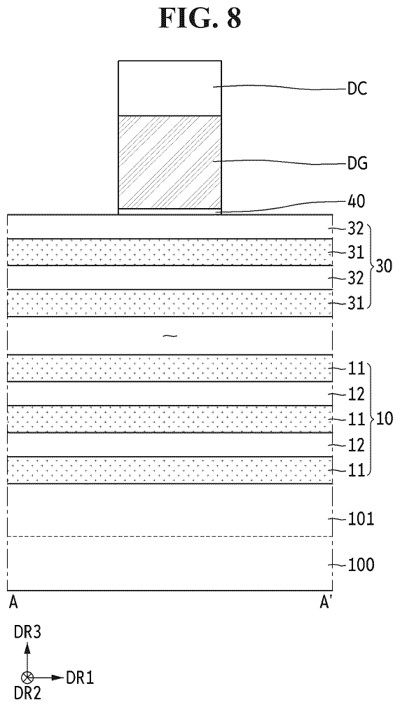

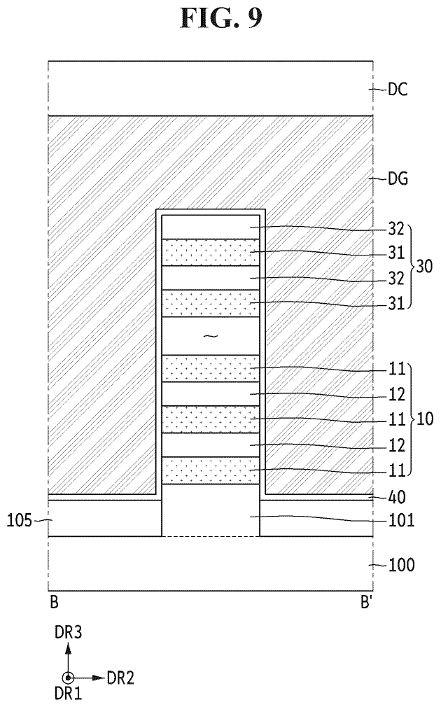

Referring to FIGS. 8 and 9, the isolation material layer 20 (see FIGS. 6 and 7) may be etched. For example, the isolation material layer 20 (see FIGS. 6 and 7) may be etched by a wet etching process.

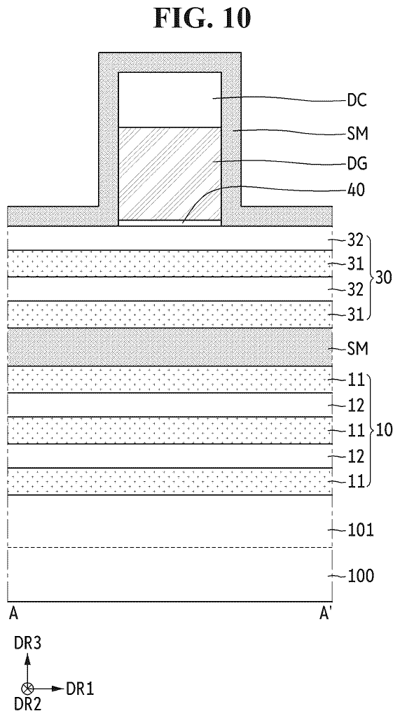

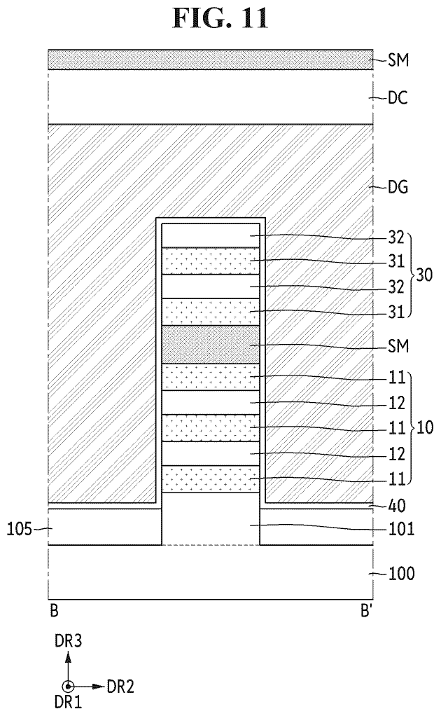

Referring to FIGS. 10 and 11, a spacer material layer SM may be formed to cover the sidewalls of the dummy gate DG, the sidewalls and upper surface of the dummy capping pattern DC, and the upper surfaces of the first stacked structure 10, the second stacked structure 30, and the field insulating layer 105. The spacer material layer SM may fill the portion where the isolation material layer 20 (see FIGS. 6 and 7) is etched. For example, the spacer material layer SM may be formed conformally. For example, the spacer material layer SM may include at least one of silicon nitride (SiN), silicon oxynitride (SiON), silicon carbonitride (SiCN), silicon oxycarbonitride (SiOCN), silicon boron nitride (SiBN), silicon oxyboron nitride (SiOBN), silicon oxycarbide (SiOC), and combinations thereof.

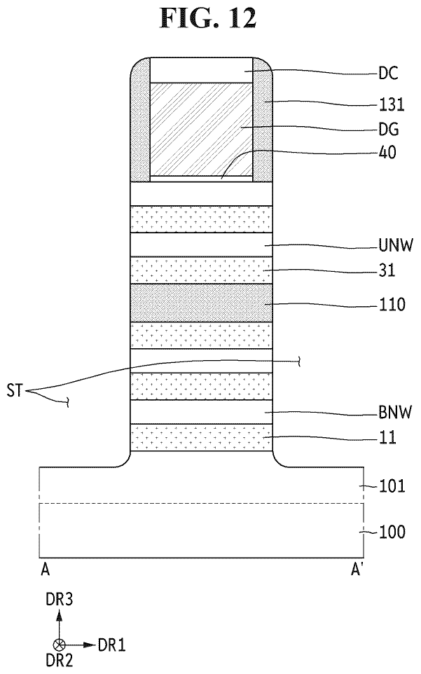

Referring to FIG. 12, the first laminate structure 10 (see FIGS. 10 and 11), the spacer material layer SM (see FIGS. 10 and 11), and the second laminate structure 30 (see FIGS. 10 and 11) may be etched using the dummy capping pattern DC and the dummy gate DG as masks to form a source/drain trench ST. For example, the source/drain trench ST may be formed on both (e.g., opposing) sides of the dummy gate DG in the first horizontal direction DR1. For example, the source/drain trench ST may extend into the inside of the active pattern 101.

For example, while the source/drain trench ST is being formed, the spacer material layer SM (see FIGS. 10 and 11) formed on the upper surface of the dummy capping pattern DC and a portion of the dummy capping pattern DC may be etched away. After the source/drain trench ST is formed, the spacer material layer SM (see FIGS. 10 and 11) remaining on both (e.g., opposing) sidewalls in the first horizontal direction DR1 of each of the dummy gate DG and the dummy capping pattern DC may be defined as a gate spacer 131.

For example, after the source/drain trench ST is formed, the first semiconductor layer 12 (see FIGS. 10 and 11) remaining under the dummy gate DG may be defined as a plurality of bottom nanosheets BNW. After the source/drain trench ST is formed, the second semiconductor layer 32 (see FIGS. 10 and 11) remaining under the dummy gate DG may be defined as a plurality of upper nanosheets UNW. Further, after the source/drain trench ST is formed, the spacer material layer SM (see FIGS. 10 and 11) remaining between the first sacrificial layer 11 and the second sacrificial layer 31 may be defined as a nanosheet isolation layer 110.

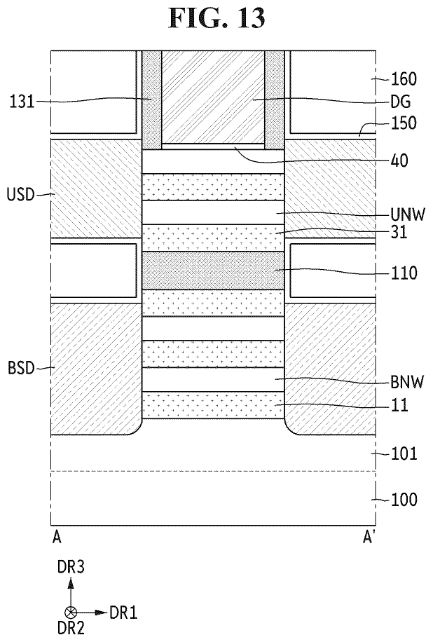

Referring to FIG. 13, the bottom source/drain region BSD and the upper source/drain region USD may be formed inside the source/drain trench ST (see FIG. 12). The bottom source/drain region BSD may be in contact with both (e.g., opposing) sidewalls of the plurality of bottom nanosheets BNW in the first horizontal direction DR1. The upper source/drain region USD may be in contact with both (e.g., opposing) sidewalls of the plurality of upper nanosheets UNW in the first horizontal direction DR1. The upper source/drain region USD may be spaced apart from the bottom source/drain region BSD in the vertical direction DR3.

Additionally, the first etching stop layer 150 and a first interlayer insulating layer 160 may be formed on the exposed surface of each of the field insulating layer 105, the bottom source/drain region BSD, the upper source/drain region USD, the first sacrificial layer 11, the second sacrificial layer 31, the nanosheet isolation layer 110, and the gate spacer 131. The first interlayer insulating layer 160 may be formed on the first etching stop layer 150. For example, the first etching stop layer 150 may be conformally formed. Subsequently, by performing a planarization process, the upper surface of the dummy gate DG may be exposed.

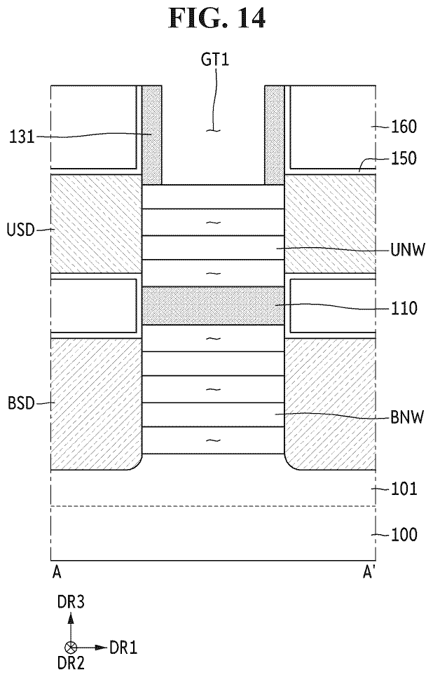

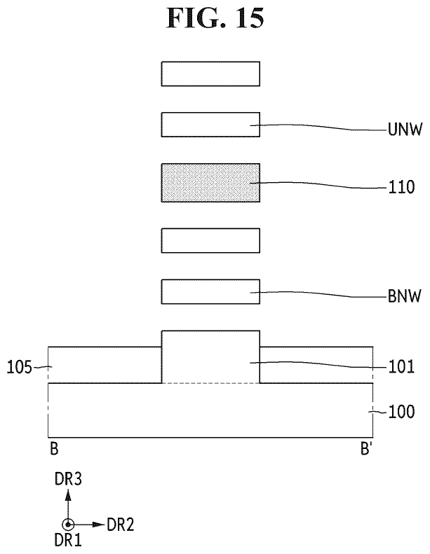

Referring to FIGS. 14 and 15, each of the dummy gate DG (see FIG. 13), the pad oxide layer 40 (see FIG. 13), the first sacrificial layer 11 (see FIG. 13), and the second sacrificial layer 31 (see FIG. 13) may be etched. The portion where each of the dummy gate DG (see FIG. 13), the pad oxide layer 40 (see FIG. 13), the first sacrificial layer 11 (see FIG. 13), and the second sacrificial layer 31 (see FIG. 13) are etched may be defined as the first gate trench GT1.

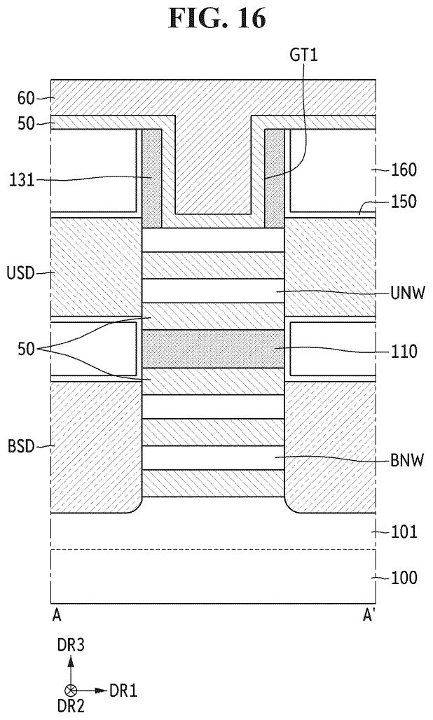

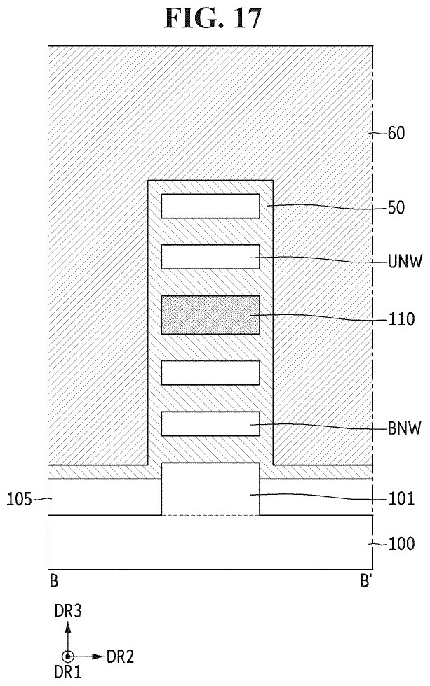

Referring to FIGS. 16 and 17, a first protective layer 50 may be formed inside the first gate trench GT1. For example, the first protective layer 50 may surround each of the plurality of bottom nanosheets BNW, the nanosheet isolation layer 110, and the plurality of upper nanosheets UNW inside the first gate trench GT1. The first protective layer 50 may also be formed on the upper surface of the field insulating layer 105 inside the first gate trench GT1 The first protective layer 50 may be formed on the sidewalls of the gate spacer 131 inside the first gate trench GT1. For example, the first protective layer 50 may also be formed on the upper surface of each of the gate spacer 131, the first etching stop layer 150, and the first interlayer insulating layer 160. For example, the first protective layer 50 may include aluminum oxide (AlO), lanthanum oxide (LaO), or lanthanum aluminum oxide (LaAlO). Subsequently, a second protective layer 60 may be formed on the first protective layer 50. For example, the second protective layer 60 may fill the remaining portion of the first gate trench GT1 on the first protective layer 50. For example, the second protective layer 60 may include polycarbon (Poly-C), silicon carbide (SiC), or spin on hardmask (SOH).

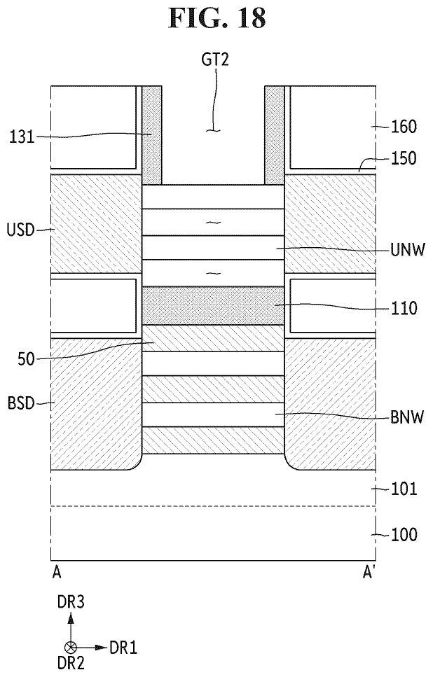

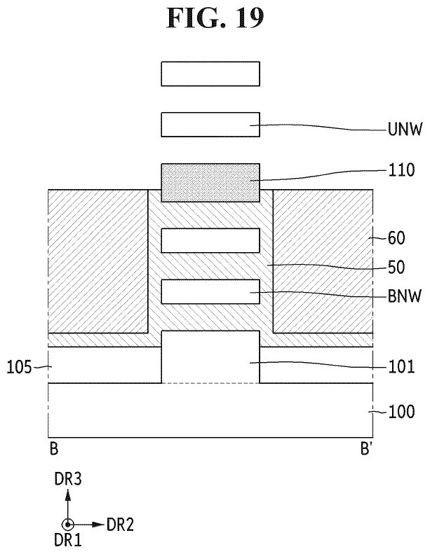

Referring to FIGS. 18 and 19, a portion of the first protective layer 50 and a portion of the second protective layer 60 may be etched. For example, each of the upper surface of the remaining first protective layer 50 and the upper surface of the remaining second protective layer 60 may be formed on the sidewall of the nanosheet isolation layer 110 in the second horizontal direction DR2. After a portion of the first protective layer 50 and a portion of the second protective layer 60 are etched, the region formed on the upper surface of each of the first protective layer 50 and the second protective layer 60 inside the first gate trench GT1 (see FIG. 16) may be defined as the second gate trench GT2.

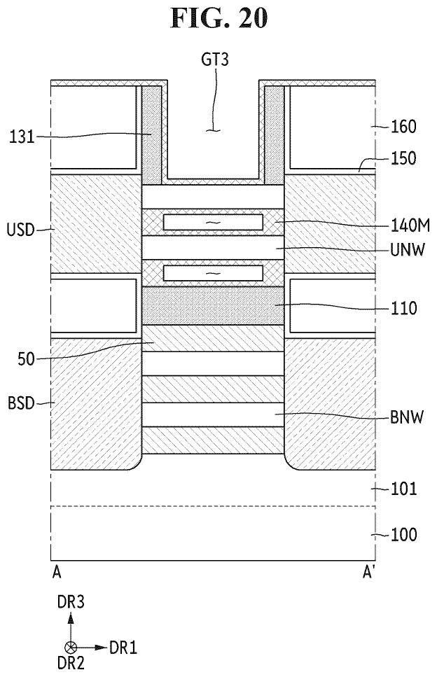

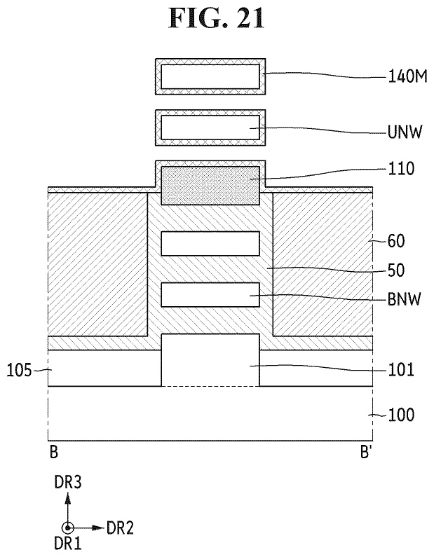

Referring to FIGS. 20 and 21, an inner spacer material layer 140M may be formed on the exposed surface of each of the nanosheet isolation layer 110, the plurality of upper nanosheets UNW, the gate spacer 131, the upper source/drain region USD, the first protective layer 50, and the second protective layer 60 inside the second gate trench GT2 (see FIG. 18). For example, the inner spacer material layer 140M may also be formed on the upper surface of each of the gate spacer 131, the first etching stop layer 150, and the first interlayer insulating layer 160. For example, the inner spacer material layer 140M may be formed in a liner shape.

For example, the thickness of the inner spacer material layer 140M in the first horizontal direction DR1 of the portion being in contact with the upper source/drain region USD may be greater than the thickness of the inner spacer material layer 140M in the vertical direction DR3 of the portion that is in contact with the upper surface and the bottom surface of the plurality of upper nanosheets UNW. For example, the inner spacer material layer 140M may include at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), and combinations thereof. After the inner spacer material layer 140M is formed, the region formed on the inner spacer material layer 140M inside the second gate trench GT2 (see FIG. 18) may be defined as a third gate trench GT3.

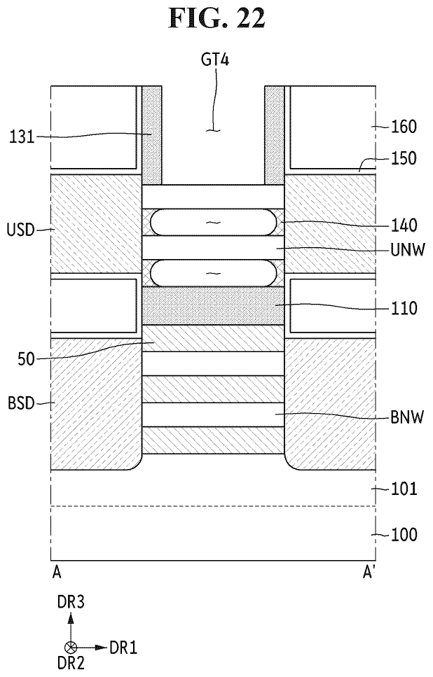

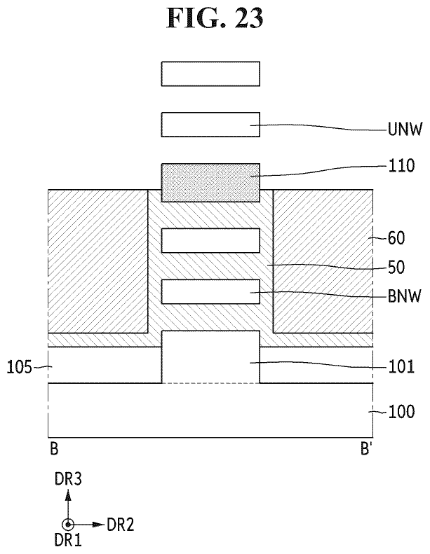

Referring to FIGS. 22 and 23, a portion of the inner spacer material layer 140M (see FIGS. 20 and 21) may be etched by performing a wet etching process. After the portion of the inner spacer material layer 140M (see FIGS. 20 and 21) is etched, the remaining inner spacer material layer 140M (see FIGS. 20 and 21) may be defined as the inner spacer 140. For example, the inner spacer 140 may be in contact with the upper source/drain region USD between the upper surface of the nanosheet isolation layer 110 and the bottom surface of the lowermost nanosheet of the plurality of upper nanosheets UNW. Additionally, the inner spacer 140 may be in contact with the upper source/drain region USD between adjacent upper nanosheets UNW. After the inner spacer 140 is formed, the remaining region inside the third gate trench GT3 (see FIG. 20) may be defined as a fourth gate trench GT4. For example, the sidewalls of the inner spacer 140 in the first horizontal direction DR1 exposed through the fourth gate trench GT4 may be formed to be concave toward the upper source/drain region USD.

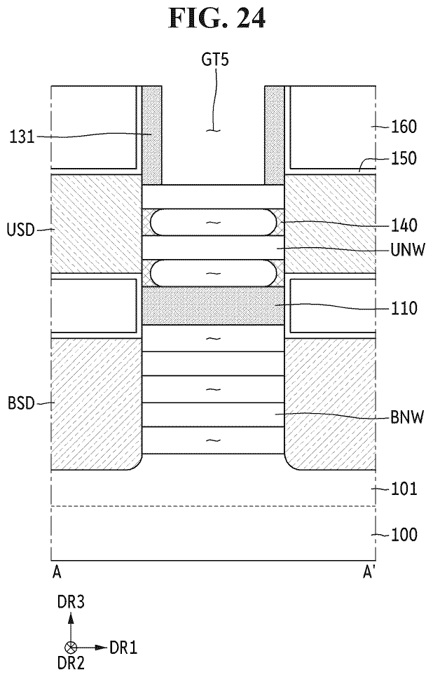

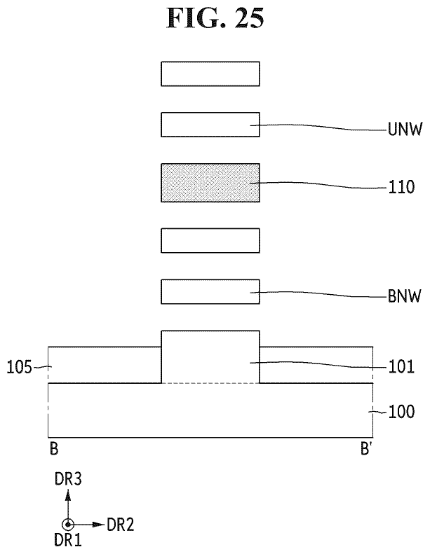

Referring to FIGS. 24 and 25, each of the first protective layer 50 (see FIGS. 22 and 23) and the second protective layer 60 (see FIGS. 22 and 23) may be etched. After each of the first protective layer 50 (see FIGS. 22 and 23) and the second protective layer 60 (see FIGS. 22 and 23) is etched, the region where each of the first protective layer (50 of FIGS. 22 and 23) and the second protective layer 60 (see FIGS. 22 and 23) is etched and the region including the fourth gate trench GT4 (see FIG. 22) may be defined as a fifth gate trench GT5.

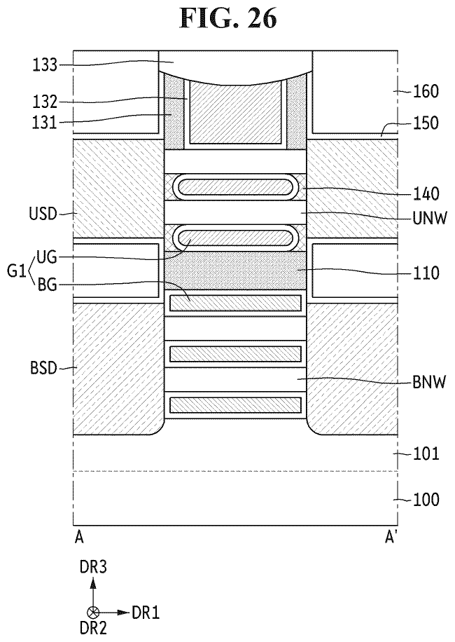

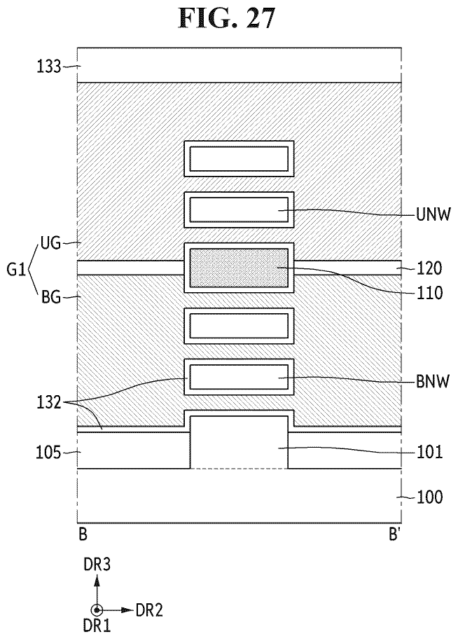

Referring to FIGS. 26 and 27, the gate insulating layer 132 may be formed along the exposed surface inside the fifth gate trench GT5 (see FIG. 24). Subsequently, inside the fifth gate trench GT5 (see FIG. 24), the gate electrode G1 and the gate isolation layer 120 may be formed on the gate insulating layer 132. For example, inside the fifth gate trench GT5 (see FIG. 24), the bottom gate electrode BG that surrounds a plurality of bottom nanosheets BNW and a portion of the nanosheet isolation layer 110 may be formed on the gate insulating layer 132. Subsequently, inside the fifth gate trench GT5 (see FIG. 24), the gate isolation layer 120 may be formed on the upper surface of the bottom gate electrode BG. Subsequently, inside the fifth gate trench GT5 (see FIG. 24), the upper gate electrode UG may be formed on the upper surface of the gate isolation layer 120. For example, the upper gate electrode UG may surround another portion of the nanosheet isolation layer 110 and a plurality of upper nanosheets UNW. Subsequently, the capping pattern 133 may be formed on the first etching stop layer 150, the gate spacer 131, the gate insulating layer 132, and the upper surface of the upper gate electrode UG.

Referring to FIGS. 2 and 3, the first source/drain contact CA1 may be formed on the first side of the upper gate electrode UG, and the second source/drain contact CA2 may be formed on the second side of the upper gate electrode UG. For example, the first source/drain contact CA1 may penetrate the first interlayer insulating layer 160 and the first etching stop layer 150 in the vertical direction DR3 and extend into the inside of the upper source/drain region USD disposed on the first side of the upper gate electrode UG. The second source/drain contact CA2 may penetrate the first interlayer insulating layer 160 and the first etching stop layer 150 in the vertical direction DR3 and extend into the inside of the upper source/drain region USD disposed on the second side of the upper gate electrode UG. Further, the silicide layer SL may be formed along the interface between each of the first and second source/drain contacts CA1, CA2 and the upper source/drain region USD. Further, a gate contact CB may be formed that penetrates the capping pattern 133 in the vertical direction DR3 and connects to the upper gate electrode UG.

Subsequently, the second etching stop layer 170 and the second interlayer insulating layer 180 may be formed sequentially on the upper surface of each of the first interlayer insulating layer 160, the capping pattern 133, the gate contact CB, and the first and second source/drain contacts CA1, CA2. Subsequently, the first via V1 penetrating the second interlayer insulating layer 180 and the second etching stop layer 170 in the vertical direction DR3 to connect to the first source/drain contact CA1 may be formed. The second via V2 penetrating the second interlayer insulating layer 180 and the second etching stop layer 170 in the vertical direction DR3 to connect to the second source/drain contact CA2 may be formed. The third via V3 penetrating the second interlayer insulating layer 180 and the second etching stop layer 170 in the vertical direction DR3 to connect to the gate contact CB may be formed. Through such a fabrication process, the semiconductor device illustrated in FIGS. 2 and 3 may be fabricated.

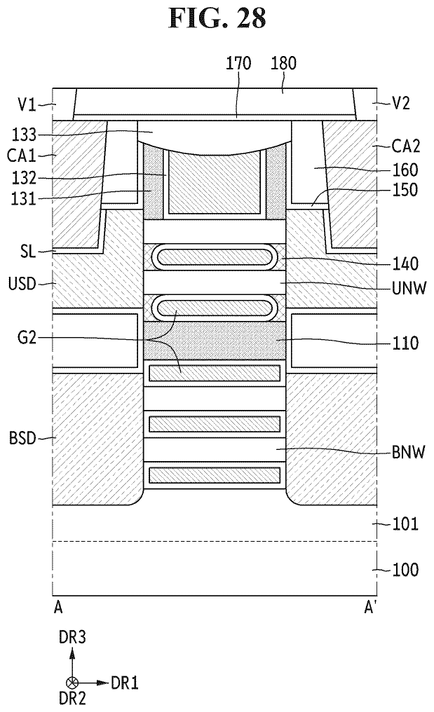

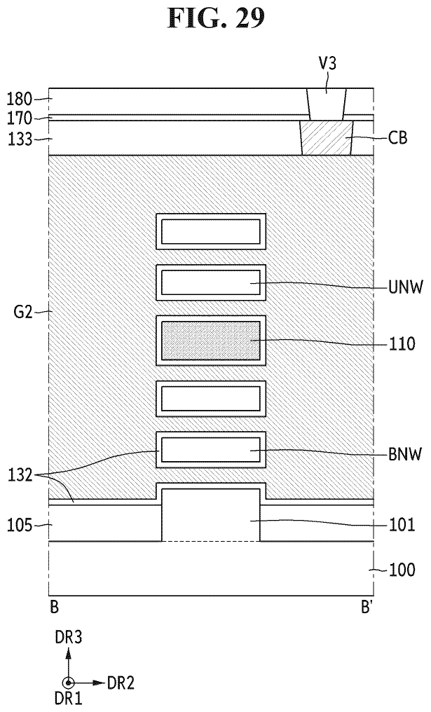

Hereinafter, the semiconductor device according to some other example embodiments of the present disclosure will be described with reference to FIGS. 28 and 29. The description will focus on the differences from the semiconductor device illustrated in FIGS. 1 to 3.

FIGS. 28 and 29 are cross-sectional views for explaining semiconductor devices according to some other example embodiments of the present disclosure.

Referring to FIGS. 28 and 29, in the semiconductor device according to some other example embodiments of the present disclosure, a single gate electrode G2 may surround each of the plurality of bottom nanosheets BNW, the nanosheet isolation layer 110, and the plurality of upper nanosheets UNW.

For example, the gate electrode G2 surrounding each of the plurality of bottom nanosheets BNW, the nanosheet isolation layer 110, and the plurality of upper nanosheets UNW may be formed as an integrated unit or unitary member. In other words, the gate electrode G2 surrounding the plurality of bottom nanosheets BNW is not electrically isolated from the gate electrode G2 surrounding the plurality of upper nanosheets UNW.

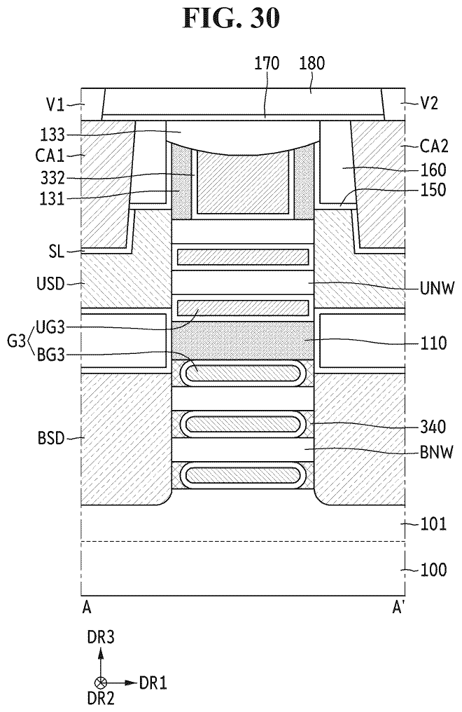

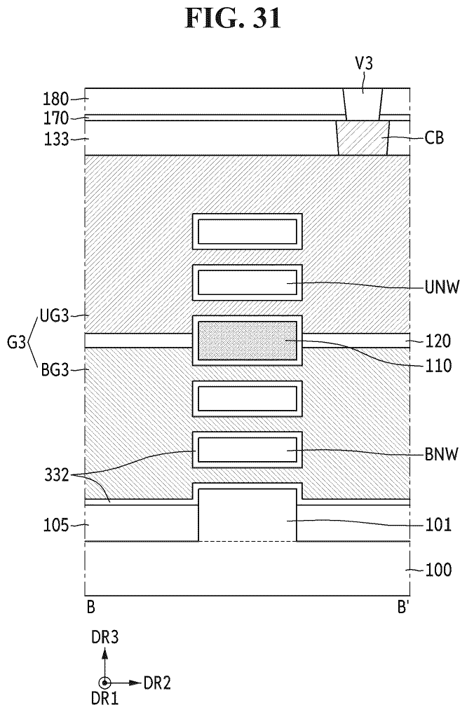

Hereinafter, the semiconductor device according to some other example embodiments of the present disclosure will be described with reference to FIGS. 30 and 31. The description will focus on the differences from the semiconductor device illustrated in FIGS. 1 to 3.

FIGS. 30 and 31 are cross-sectional views for explaining the semiconductor device according to some other example embodiments of the present disclosure.

Referring to FIGS. 30 and 31, in the semiconductor device according to some other example embodiments of the present disclosure, the inner spacer 340 is disposed on both (e.g., opposing) sidewalls of the bottom gate electrode BG3 in the first horizontal direction DR1, while the inner spacer 340 is not disposed on both (e.g., opposing) sidewalls of the upper gate electrode UG3 in the first horizontal direction DR1.

For example, the gate electrode G3 may include the bottom gate electrode BG3 surrounding the plurality of bottom nanosheets BNW and a portion of the nanosheet isolation layer 110, and the upper gate electrode UG3 surrounding another portion of the nanosheet isolation layer 110 and the plurality of upper nanosheets UNW.

For example, the inner spacer 340 may be disposed on both (e.g., opposing) sidewalls of the bottom gate electrode BG3 in the first horizontal direction DR1 between the adjacent bottom nanosheets BNW. The inner spacer 340 may be disposed on both (e.g., opposing) sidewalls of the bottom gate electrode BG3 in the first horizontal direction DR1 between the upper surface of the active pattern 101 and the bottom surface of the lowermost nanosheet of the plurality of bottom nanosheets BNW. The inner spacer 340 may be disposed on both (e.g., opposing) sidewalls of the bottom gate electrode BG3 in the first horizontal direction DR1 between the bottom surface of the nanosheet isolation layer 110 and the upper surface of the uppermost nanosheet of the plurality of bottom nanosheets BNW. The inner spacer 340 may be disposed between the bottom gate electrode BG3 and the bottom source/drain region BSD.

However, the inner spacer 340 is not disposed on both (e.g., opposing) sidewalls of the upper gate electrode UG3 in the first horizontal direction DR1 between the adjacent upper nanosheets UNW. The inner spacer 340 is not disposed on both (e.g., opposing) sidewalls of the upper gate electrode UG3 in the first horizontal direction DR1 between the upper surface of the nanosheet isolation layer 110 and the bottom surface of the lowermost nanosheet of the plurality of upper nanosheets UNW.

For example, the inner spacer 340 may be in contact with the sidewall of the bottom source/drain region BSD in the first horizontal direction DR1. However, the inner spacer 340 is not in contact with the upper source/drain region USD. That is, the upper source/drain region USD may be free of the inner spacers 340 between the upper source/drain region USD and the upper gate UG. For example, the inner spacer 340 may be in contact with the plurality of bottom nanosheets BNW. However, the inner spacer 340 is not in contact with the plurality of upper nanosheets UNW. That is, the upper nanosheets UNW may be free of the inner spacers 340 therebetween. For example, the inner spacer 340 may be in contact with the bottom surface of the nanosheet isolation layer 110. For example, the inner spacer 340 may be in contact with the gate insulating layer 332 between the bottom gate electrode BG3 and the bottom source/drain region BSD.

For example, the plurality of upper nanosheets UNW, the upper gate electrode UG3, and the upper source/drain region USD may form a PMOS transistor. Further, the plurality of bottom nanosheets BNW, the bottom gate electrode BG3, and the bottom source/drain region BSD may form an NMOS transistor. In other words, the inner spacer 340 is disposed on the sidewall in the first horizontal direction DR1 of the bottom gate electrode BG3 forming the NMOS transistor, and is not disposed on the sidewall in the first horizontal direction DR1 of the upper gate electrode UG3 forming the PMOS transistor.

Hereinafter, the method of fabricating a semiconductor device according to some other example embodiments of the present disclosure will be described with reference to FIGS. 30 to 44. The description will focus on the differences from the method of fabricating the semiconductor device illustrated in FIGS. 4 to 27.

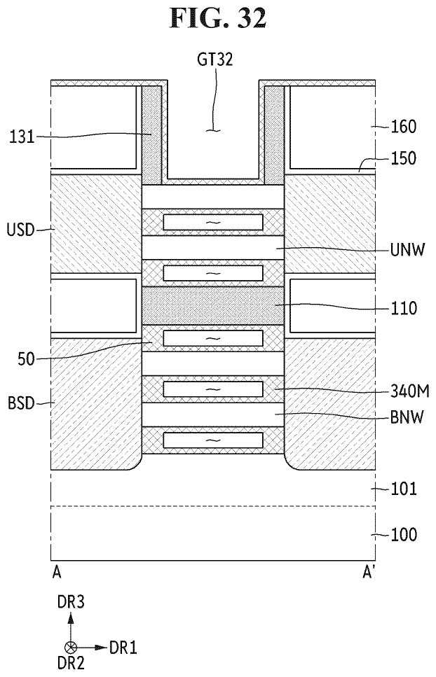

FIGS. 32 to 44 are intermediate stage diagrams for explaining the method of fabricating of a semiconductor device according to some other example embodiments of the present disclosure.

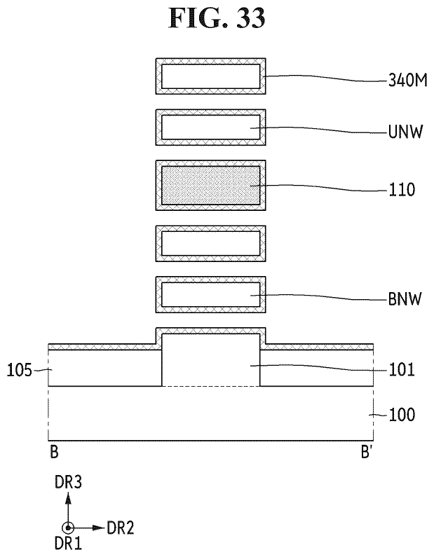

Referring to FIGS. 32 and 33, after performing the fabrication process illustrated in FIGS. 4 to 15, the inner spacer material layer 340M may be formed on the exposed surface of each of the active pattern 101, the plurality of bottom nanosheets BNW, the nanosheet isolation layer 110, the plurality of upper nanosheets UNW, the gate spacer 131, the bottom source/drain region BSD, and the upper source/drain region USD inside the first gate trench GT1 (see FIG. 14). For example, the inner spacer material layer 340M may also be formed on the upper surface of each of the gate spacer 131, the first etching stop layer 150, and the first interlayer insulating layer 160. For example, the inner spacer material layer 340M may be formed in a liner shape. After the inner spacer material layer 340M is formed, the region formed on the inner spacer material layer 340M inside the first gate trench GT1 (see FIG. 14) may be defined as the second gate trench GT32.

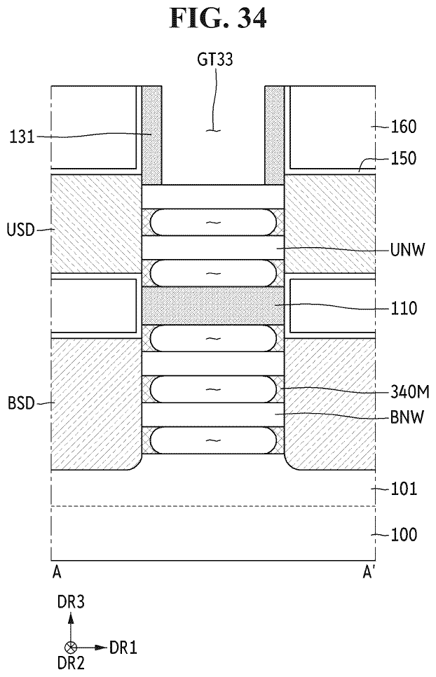

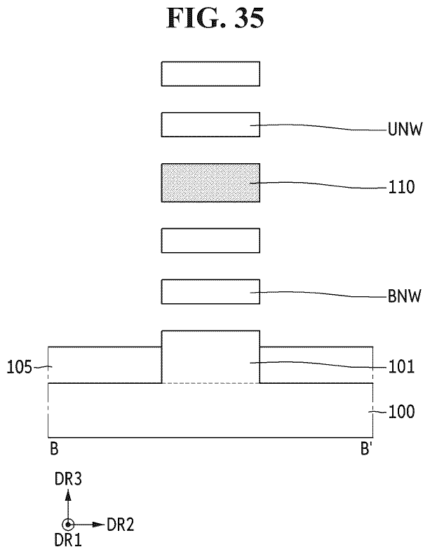

Referring to FIGS. 34 and 35, a portion of the inner spacer material layer 340M may be etched by performing a wet etching process. For example, after the portion of the inner spacer material layer 340M is etched, the remaining inner spacer material layer 340M may be in contact with each of the bottom source/drain region BSD and the upper source/drain region USD. After a portion of the inner spacer material layer 340M has been etched, the remaining region inside the second gate trench GT32 (see FIG. 32) may be defined as a third gate trench GT33. For example, the sidewall of the inner spacer material layer 340M exposed through the third gate trench GT33 in the first horizontal direction DR1 may be formed concave toward each of the bottom source/drain region BSD and the upper source/drain region USD.

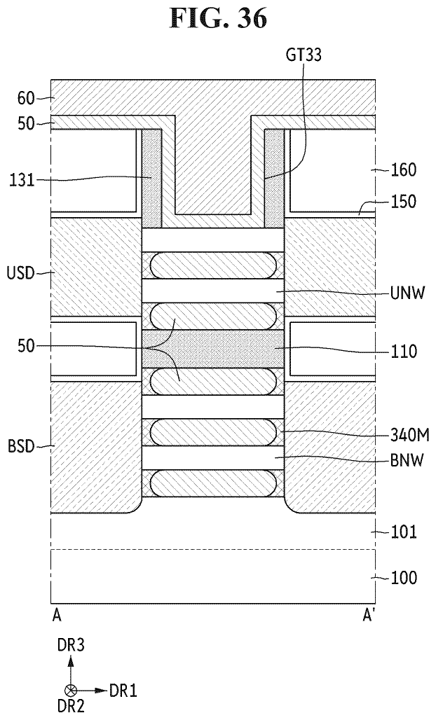

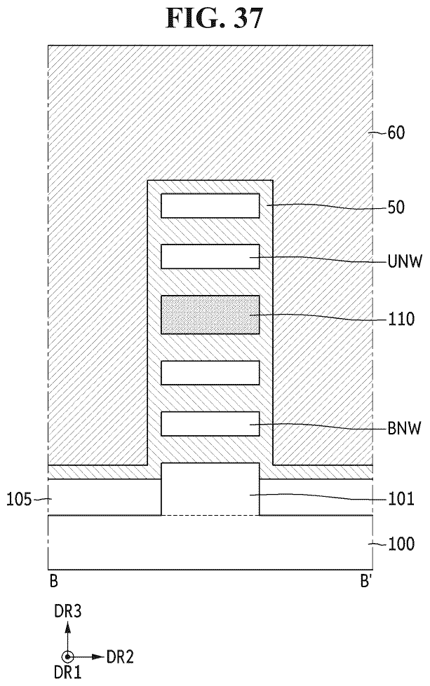

Referring to FIGS. 36 and 37, a first protective layer 50 may be formed inside the third gate trench GT33. For example, the first protective layer 50 may surround each of the plurality of bottom nanosheets BNW, the nanosheet isolation layer 110, and the plurality of upper nanosheets UNW inside the third gate trench GT33. The first protective layer 50 may also be formed on the upper surface of the field insulating layer 105 inside the third gate trench GT3. The first protective layer 50 may be formed on the sidewalls of the gate spacer 131 inside the third gate trench GT3. For example, the first protective layer 50 may be formed on the upper surface of each of the gate spacer 131, the first etching stop layer 150, and the first interlayer insulating layer 160. Subsequently, a second protective layer 60 may be formed on the first protective layer 50. For example, the second protective layer 60 may fill the remaining portion of the third gate trench GT3 on the first protective layer 50.

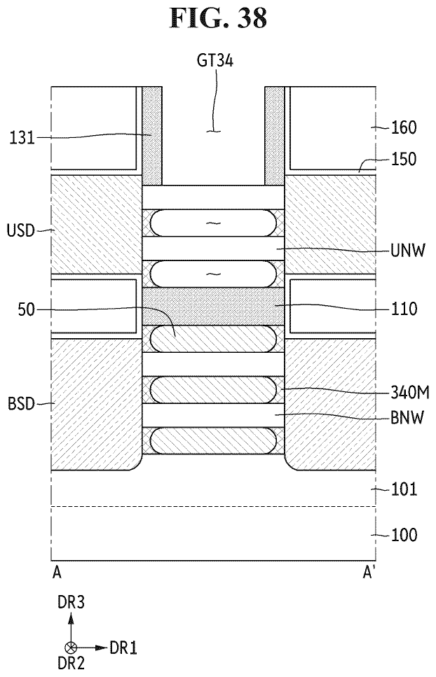

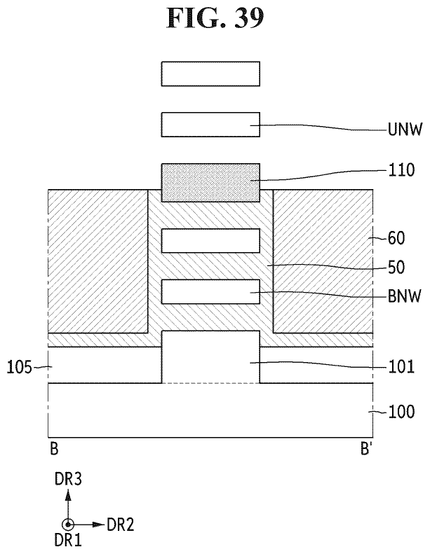

Referring to FIGS. 38 and 39, a portion of the first protective layer 50 and a portion of the second protective layer 60 may be etched. For example, each of the upper surface of the remaining first protective layer 50 and the upper surface of the remaining second protective layer 60 may be formed on the sidewall of the nanosheet isolation layer 110 in the second horizontal direction DR2. After a portion of the first protective layer 50 and a portion of the second protective layer 60 are etched, the region formed on the upper surface of each of the first protective layer 50 and the second protective layer 60 inside the third gate trench GT33 (see FIG. 36) may be defined as a fourth gate trench GT34. For example, the inner spacer material layer 340M that is in contact with the upper source/drain region USD may be exposed through the fourth gate trench GT34.

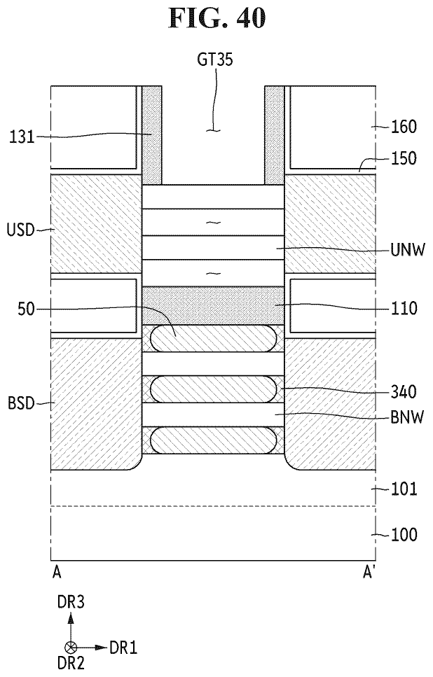

Referring to FIG. 40, the inner spacer material layer 340M (see FIG. 38) exposed through the fourth gate trench GT34 (see FIG. 38) may be etched. After the inner spacer material layer 340M exposed through the fourth gate trench GT34 (see FIG. 38) is etched, the remaining inner spacer material layer 340M that is in contact with the bottom source/drain region BSD may be defined as the inner spacer 340. After the inner spacer material layer 340M (see FIG. 38) exposed through the fourth gate trench GT34 (see FIG. 38) is etched, the region formed on the upper surface of each of the first protective layer 50 and the second protective layer 60 (see FIG. 39) inside the fourth gate trench GT34 (see FIG. 38) may be defined as a fifth gate trench GT35. For example, the upper source/drain region USD may be exposed through the fifth gate trench GT35.

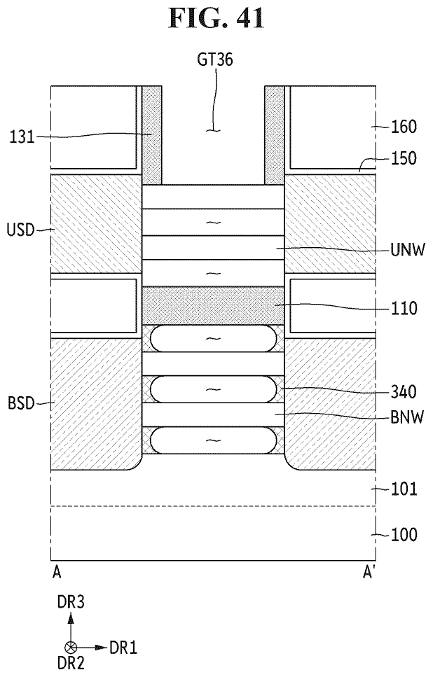

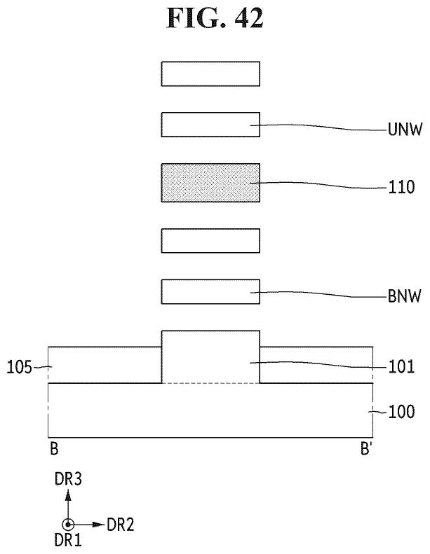

Referring to FIGS. 41 and 42, each of the first protective layer 50 (see FIG. 40) and the second protective layer 60 (see FIG. 39) may be etched. After each of the first protective layer 50 (see FIG. 40) and the second protective layer 60 (see FIG. 39) is etched, the region in which each of the first protective layer 50 (see FIG. 40) and the second protective layer 60 (see FIG. 39) is etched and the region including the fifth gate trench GT35 (see FIG. 40) may be defined as a sixth gate trench GT36.

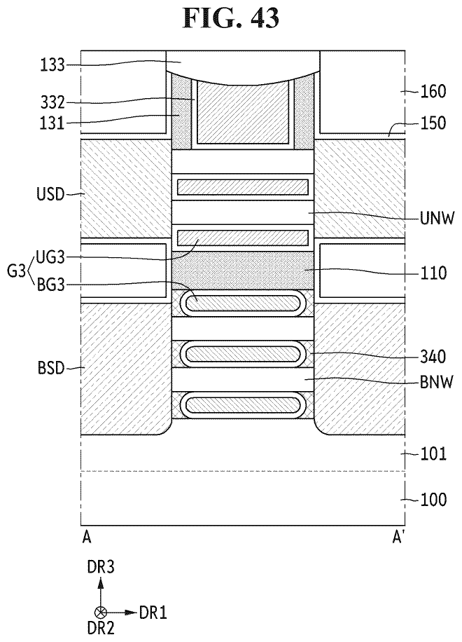

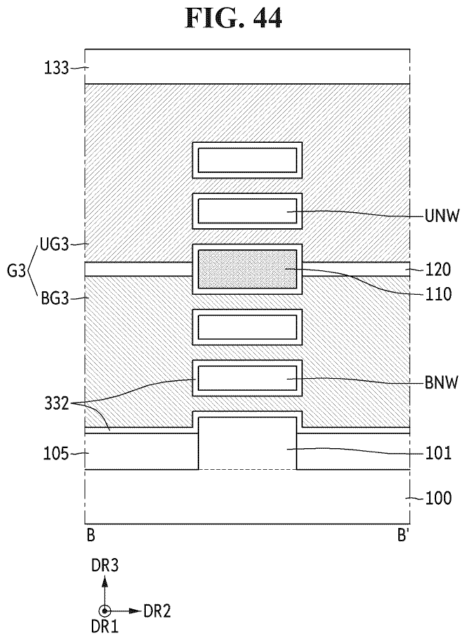

Referring to FIGS. 43 and 44, the gate insulating layer 332 may be formed along the exposed surface inside the sixth gate trench GT36 (see FIG. 41). Subsequently, inside the sixth gate trench GT36 (see FIG. 41), the gate electrode G3 and the gate isolation layer 120 may be formed on the gate insulating layer 332. For example, the gate electrode G3 may include the bottom gate electrode BG3 and the upper gate electrode UG3. The gate isolation layer 120 may be formed between the bottom gate electrode BG3 and the upper gate electrode UG3. Subsequently, the capping pattern 133 may be formed on the first etching stop layer 150, the gate spacer 131, the gate insulating layer 332, and the upper surface of the upper gate electrode UG3.

Referring to FIG. 30 and FIG. 31, a first source/drain contact CA1 may be formed on a first side of the upper gate electrode UG, and a second source/drain contact CA2 may be formed on a second side of the upper gate electrode UG. Additionally, a silicide layer SL may be formed along the interface between each of the first and second source/drain contacts CA1, CA2 and the upper source/drain region USD. Further, a gate contact CB may be formed that penetrates the capping pattern 133 in the vertical direction DR3 and connects to the upper gate electrode UG3.

Subsequently, the second etching stop layer 170 and the second interlayer insulating layer 180 may be formed sequentially on the upper surface of each of the first interlayer insulating layer 160, the capping pattern 133, the gate contact CB, and the first and second source/drain contacts CA1, CA2. Subsequently, each of the first to third vias V1, V2, V3 may be formed inside the second etching stop layer 170 and the second interlayer insulating layer 180. Through such a fabrication process, the semiconductor device illustrated in FIGS. 30 and 31 may be fabricated.

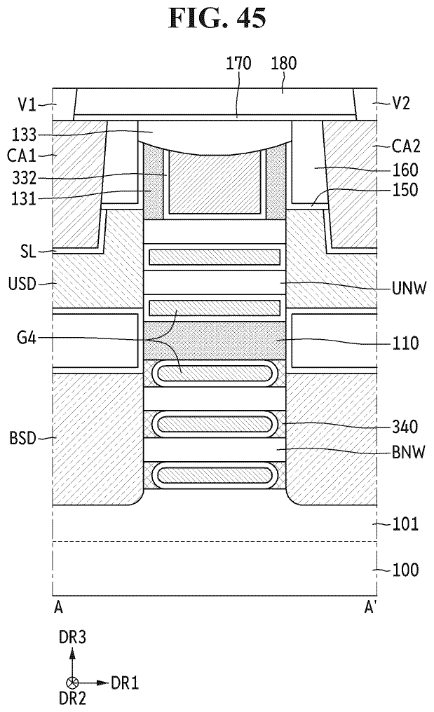

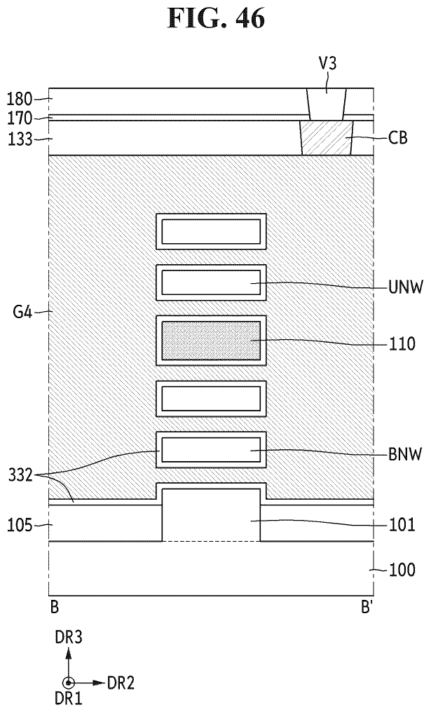

Hereinafter, the semiconductor device according to some other example embodiments of the present disclosure will be described with reference to FIGS. 45 and 46. The description will focus on the differences from the semiconductor device illustrated in FIGS. 30 and 31.

FIGS. 45 and 46 are cross-sectional views for explaining the semiconductor device according to another several embodiments of the present disclosure.

Referring to FIGS. 45 and 46, in the semiconductor device according to some other example embodiments of the present disclosure, a single gate electrode G4 may surround each of the plurality of bottom nanosheets BNW, the nanosheet isolation layer 110, and the plurality of upper nanosheets UNW.

For example, the gate electrode G4 surrounding each of the plurality of bottom nanosheets BNW, the nanosheet isolation layer 110, and the plurality of upper nanosheets UNW may be formed as an integrated unit or unitary member. In other words, the gate electrode G4 surrounding the plurality of bottom nanosheets BNW is not electrically isolated from the gate electrode G4 surrounding the plurality of upper nanosheets UNW.

While example embodiments according to the present disclosure have been described above with reference to the accompanying drawings, it will be understood that the present disclosure is not limited to the above embodiments and may be fabricated in a variety of different forms, and those of ordinary skill in the art to which the present disclosure belongs, may recognize that it may be implemented in other specific forms without changing the technical idea or essential features of the present disclosure. Therefore, it should be understood that the above-described embodiments are exemplary in all respects and not restrictive.

What is claimed is:

1. A semiconductor device comprising:
a substrate;
an active pattern extending in a first direction on the substrate;
a plurality of lower nanosheets stacked on the active pattern and spaced apart from each other in a vertical direction perpendicular to a surface of the substrate;
a nanosheet isolation layer on an upper surface of an uppermost nanosheet of the plurality of lower nanosheets, the nanosheet isolation layer including an insulating material;
a plurality of upper nanosheets stacked on an upper surface of the nanosheet isolation layer and spaced apart from each other in the vertical direction;
a gate electrode extending in a second direction that intersects the first direction on the active pattern, the gate electrode extending on the plurality of lower nanosheets, the nanosheet isolation layer, and the plurality of upper nanosheets; and
inner spacers on opposing sidewalls of the gate electrode in the first direction, wherein:
the inner spacers are between adjacent ones of the upper nanosheets, and the plurality of lower nanosheets are free of the inner spacers therebetween; or
the inner spacers are between adjacent ones of the lower nanosheets, and the plurality of upper nanosheets are free of the inner spacers therebetween.

2. The semiconductor device of claim 1, further comprising:
a lower source/drain region on the active pattern and in contact with respective sidewalls of the lower nanosheets in the first direction; and
an upper source/drain region spaced apart from the lower source/drain region in the vertical direction and in contact with respective sidewalls of the upper nanosheets in the first direction.

3. The semiconductor device of claim 2, wherein the lower source/drain region is free of contact with the inner spacers, and
wherein the upper source/drain region is in contact with at least one of the inner spacers.

4. The semiconductor device of claim 2, wherein the lower source/drain region is in contact with at least one of the inner spacers, and
wherein the upper source/drain region is free of contact with the inner spacers.

5. The semiconductor device of claim 1, wherein the inner spacers are in contact with the nanosheet isolation layer, and wherein:
the inner spacers are between the upper surface of the uppermost nanosheet of the plurality of lower nanosheets and a lower surface of the nanosheet isolation layer; or
the inner spacers are between the upper surface of the nanosheet isolation layer and a lower surface of a lowermost nanosheet of the plurality of upper nanosheets.

6. The semiconductor device of claim 2, further comprising:
a gate insulating layer between the gate electrode and respective ones of the plurality of lower nanosheets, between the gate electrode and the nanosheet isolation layer, and between the gate electrode and the plurality of upper nanosheets,
wherein the gate insulating layer is in contact with the inner spacers.

7. The semiconductor device of claim 6, further comprising:
an interlayer insulating layer between an upper surface of the lower source/drain region and a lower surface of the upper source/drain region; and
an etching stop layer between a sidewall of the nanosheet isolation layer in the first direction and the interlayer insulating layer,
wherein the etch stop layer is in contact with the inner spacers and is in contact with the gate insulating layer.

8. The semiconductor device of claim 1, wherein the inner spacers on the opposing sidewalls of the gate electrode in the first direction are between the adjacent ones of the upper nanosheets, and the plurality of lower nanosheets are free of the inner spacers therebetween.

9. The semiconductor device of claim 1, wherein the inner spacers on the opposing sidewalls of the gate electrode in the first direction are between the adjacent ones of the lower nanosheets, and the plurality of upper nanosheets are free of the inner spacers therebetween.

10. The semiconductor device of claim 1, wherein the gate electrode comprises
a lower gate electrode extending on the plurality of lower nanosheets and on a portion of the nanosheet isolation layer; and
an upper gate electrode spaced from the lower gate electrode in the vertical direction, the upper gate electrode extending on another portion of the nanosheet isolation layer and on the plurality of upper nanosheets.

11. The semiconductor device of claim 1, wherein respective sidewalls in the first direction of the plurality of lower nanosheets, the nanosheet isolation layer, and the plurality of upper nanosheets are aligned in the vertical direction.

12. A semiconductor device comprising:
a substrate;
an active pattern extending in a first direction on the substrate;
a plurality of nanosheets stacked on the active pattern and spaced apart from each other in a vertical direction perpendicular to a surface of the substrate;
a gate electrode extending in a second direction that intersects the first direction on the active pattern, the gate electrode extending on the plurality of nanosheets;
a lower source/drain region on the active pattern at one side of the gate electrode in the first direction;
an upper source/drain region on the lower source/drain region at the one side of the gate electrode in the first direction, wherein the upper source/drain region is spaced apart from the lower source/drain region in the vertical direction; and
an inner spacer between the gate electrode and one of the lower source/drain region or the upper source/drain region,
wherein the gate electrode and another of the lower source/drain region or the upper source/drain region are free of the inner spacer therebetween.

13. The semiconductor device of claim 12, wherein the plurality of nanosheets comprise:
a plurality of lower nanosheets stacked on the active pattern and spaced apart from each other in the vertical direction, wherein the plurality of lower nanosheets are in contact with a sidewall of the lower source/drain region in the first direction; and
a plurality of upper nanosheets stacked on the plurality of lower nanosheets and spaced apart from each other in the vertical direction, wherein the plurality of upper nanosheets are in contact with a sidewall of the upper source/drain region in the first direction.

14. The semiconductor device of claim 13, wherein opposing sidewalls of a lower portion of the gate electrode are free of the inner spacer in the first direction between adjacent ones of the lower nanosheets, and
wherein the inner spacer is on opposing sidewalls of an upper portion of the gate electrode in the first direction between adjacent ones of the upper nanosheets.

15. The semiconductor device of claim 13, wherein the inner spacer is on opposing sidewalls of a lower portion of the gate electrode in the first direction between adjacent ones of the lower nanosheets, and
wherein opposing sidewalls of an upper portion of the gate electrode are free of the inner spacer in the first direction between adjacent ones of the upper nanosheets.

16. The semiconductor device of claim 12, wherein a sidewall of the inner spacer in the first direction facing the gate electrode is concave toward the one of the lower source/drain region or the upper source/drain region.

17. The semiconductor device of claim 12, wherein the inner spacer is in direct contact with the upper source/drain region, and wherein the lower source/drain region is free of the inner spacer thereon.

18. The semiconductor device of claim 12, wherein the inner spacer is in direct contact with the lower source/drain region, and wherein the upper source/drain region is free of the inner spacer thereon.

19. The semiconductor device of claim 12, wherein the gate electrode comprises:
a lower gate electrode overlapping with the lower source/drain region in the first direction; and
an upper gate electrode overlapping with the upper source/drain region in the first direction and spaced apart from the lower gate electrode in the vertical direction.

20. A semiconductor device comprising:
a substrate;
an active pattern extending in a first direction on the substrate;
a plurality of lower nanosheets stacked on the active pattern and spaced apart from each other in a vertical direction perpendicular to a surface of the substrate;
a nanosheet isolation layer on an upper surface of an uppermost nanosheet of the plurality of lower nanosheets, the nanosheet isolation layer comprising an insulating material;
a plurality of upper nanosheets stacked on an upper surface of the nanosheet isolation layer and spaced apart from each other in the vertical direction;
a lower gate electrode extending in a second direction that intersects the first direction on the active pattern, the lower gate electrode extending on the plurality of lower nanosheets and a lower portion of the nanosheet isolation layer;
an upper gate electrode extending in the second direction and spaced apart from the lower gate electrode in the vertical direction, the upper gate electrode extending on an upper portion of the nanosheet isolation layer and the plurality of upper nanosheets;
a lower source/drain region on the active pattern and in contact with respective sidewalls of the plurality of lower nanosheets in the first direction;
an upper source/drain region on the lower source/drain region and in contact with respective sidewalls of the plurality of upper nanosheets in the first direction, the upper source/drain region spaced apart from the lower source/drain region in the vertical direction;
a gate insulating layer between the lower source/drain region and the lower gate electrode, and between the upper source/drain region and the upper gate electrode; and
an inner spacer between the upper source/drain region and the gate insulating layer on the upper gate electrode,
wherein the inner spacer directly contacts the upper source/drain region, and
wherein the gate insulating layer directly contacts the lower source/drain region.
